(19) United States
(12) Patent Application Publication
(10) Pub. No.: US 2026/0133258 A1
(43) Pub. Date: May 14, 2026

(54) SYSTEMS AND METHODS FOR MONITORING AND DIAGNOSING ELECTROCHEMICAL CELLS INCLUDING INTERLAYERS

(71) Applicant: 24M Technologies, Inc., Cambridge, MA (US)

(72) Inventors: Chad Alan HARTZOG, Columbus, IN (US); Junzheng CHEN, Concord, MA (US); Naoki OTA, Lexington, MA (US)

(21) Appl. No.: 19/379,194

(22) Filed: Nov. 4, 2025

Related U.S. Application Data
(60) Provisional application No. 63/718,265, filed on Nov. 8, 2024.

(51) Int. Cl. G01R 31/392; G01R 31/3835; G01R 35/00; H01M 10/42

(52) U.S. Cl. CPC G01R 31/392; G01R 31/3835; G01R 35/005; H01M 10/4285

(57) ABSTRACT

Embodiments described herein relate to systems and methods for evaluating electrochemical cells. In some aspects, an electrochemical cell can include a first electrode, a second electrode, and an interlayer, and the method can include performing a calibrating electrical energy transfer between the first electrode and the second electrode to develop a baseline parameter based on the calibration voltage differences. The method can further include performing an operational electrical energy transfer between the first electrode and the second electrode and developing an operational parameter based on the operational voltage differences. The method can further include diagnosing a performance issue with the electrochemical cell based on the baseline parameter and the operational parameter. In some embodiments, the calibrating electrical energy transfer can include an initial charge of the electrochemical cell and the operational electrical energy transfer can include a subsequent charge of the electrochemical cell.

### CROSS-REFERENCE TO RELATED APPLICATIONS

This application claims priority to and the benefit of U.S. Provisional Patent Application No. 63/718,265, filed Nov. 8, 2024, and titled, “Systems and Methods for Monitoring and Diagnosing Electrochemical Cells with Interlayers,” the disclosure of which is hereby incorporated by reference herein in its entirety.

### TECHNICAL FIELD

Embodiments described herein relate to dendrite detection and prevention in electrochemical cells.

### BACKGROUND

Dendrites can form in electrochemical cells via plating of electroactive material. Dendrites can form on anodes or cathodes of electrochemical cells. When dendrites are small, they do not cause significant problems, aside from the lost electroactive material. However, once a dendrite grows large enough to penetrate a separator of the electrochemical cell, a short circuit is created between the anode and the cathode. Not only does this create wasted battery material and severely impede the electrochemical cell's performance, but short circuits can cause significant safety issues. Thermal runaway can occur at or near the dendrite, creating hot spots that can ignite fires. Many dendrite detection systems do not detect the dendrite until it has already caused damage. Earlier detection of dendrites can prevent safety issues and wasted electrochemical cell materials.

### SUMMARY

Embodiments described herein relate to systems and method for evaluating electrochemical cells. In some aspects, a method of evaluating an electrochemical cell that includes a first electrode, a second electrode, and an interlayer, can include performing a calibrating electrical energy transfer between the first electrode and the second electrode to develop a baseline parameter based on the calibration voltage differences. The method can further include performing an operational electrical energy transfer between the first electrode and the second electrode and developing an operational parameter based on the operational voltage differences. The method can further include diagnosing a performance issue with the electrochemical cell based on the baseline parameter and the operational parameter. In some embodiments, the calibrating electrical energy transfer can include an initial charge of one or more electrodes of the electrochemical cell and the operational electrical energy transfer can include a subsequent charge of one or more electrodes of the electrochemical cell. In some embodiments, the calibrating electrical energy transfer can include an initial discharge of one or more electrodes of the electrochemical cell relative to anode and/or a cathode of the electrochemical cell and the operational electrical energy transfer can include a subsequent discharge of one or more electrodes of the electrochemical cell. In some embodiments, the first electrode can include an anode. In some embodiments, the first electrode can include a cathode. In some embodiments, the performance issue can include a lack of electrical connectivity between a testing circuit and the interlayer of one or more electrodes of the electrochemical cell.

In some aspects, a method of evaluating a plurality of electrochemical cells connected in parallel, each electrochemical cell of the plurality of electrochemical cells including a first electrode disposed on a first current collector, a second electrode disposed on a second current collector, a first separator, a second separator, and an interlayer disposed between the first separator and the second separator, includes: electrically coupling each interlayer of each electrochemical cell from the plurality of electrochemical cells at a common interlayer connection point; electrically coupling the first electrode of each electrochemical cell from the plurality of electrochemical cells at a common electrode connection point; and measuring a voltage between the common interlayer connection point and the common electrode connection point.

In some aspects, a system includes: an electrochemical cell, including: an anode; a cathode; a first separator disposed on the anode; a second separator disposed on the cathode; an interlayer between the first separator and the second separator; and a controller operably coupled to the electrochemical cell, the controller configured to: cause a calibrating electrical energy transfer between the anode and the cathode; determine a plurality of calibration voltage differences between at least one of the anode or the cathode and the interlayer; determine a baseline parameter based on the calibration voltage differences; cause an operational electrical energy transfer between the anode and the cathode; determine a plurality of operational voltage differences between at least one of the anode or the cathode and the interlayer; determine an operational parameter based on the operational voltage differences; and diagnose a performance issue with the electrochemical cell based on the baseline parameter and the operational parameter.

It should be appreciated that all combinations of the foregoing concepts and additional concepts discussed in greater detail herein (provided such concepts are not mutually inconsistent) are contemplated as being part of the inventive subject matter disclosed herein. In particular, all combinations of claimed subject matter appearing at the end of this disclosure are contemplated as being part of the inventive subject matter disclosed herein.

### BRIEF DESCRIPTION OF THE DRAWINGS

FIGS. 1A-1B are block diagrams of an electrochemical cell system and components thereof, according to an embodiment.

FIG. 2 is a flow diagram of a method of evaluating an electrochemical cell, according to an embodiment.

FIG. 3 is an illustration of an electrochemical cell system, according to an embodiment.

FIG. 4 is an illustration of an electrochemical cell system, according to an embodiment.

FIG. 5 is an illustration of an electrochemical cell system, according to an embodiment.

FIG. 6 is an illustration of an electrochemical cell system, according to an embodiment.

FIG. 7 is a graphical representation of a calibrating charge curve and a calibrating discharge curve, according to an embodiment.

### DETAILED DESCRIPTION

Embodiments described herein relate to dendrite detection and prevention in electrochemical cells. Electrochemical cells described herein can include an anode disposed on an anode current collector, a cathode disposed on a cathode current collector, a first separator disposed on the anode, a second separator disposed on the cathode, and an interlayer disposed between the first separator and the second separator. Interlayers can operate in an equivalent circuit model. An equivalent circuit can be utilized to determine a state of functioning of an electrochemical cell system. In addition, active manipulation and sensing of the voltage within the electrochemical cell system can be used to detect issues in the electrochemical cell system. Particularly, manipulation of voltage can be used to evaluate subtle changes or disturbances due to early dendrite formation (i.e., dendrites that have not grown large enough to penetrate either of the separators). Loss of passive component characteristics can also be used to detect open or shorted circuits to ensure connection and functionality of the interlayer.

Embodiments described herein include control systems for actuating loads to an electrochemical cell and measuring resultant conditions to evaluate the health of the interlayer. In some embodiments, systems evaluated can include sets or stacks of electrochemical cells and embodiments described herein can evaluate multiple electrochemical cells at a time. In some embodiments, the interlayers described herein can include any of the properties described in U.S. Patent Publication No. 2022/0352597 (“the '597 publication), filed Apr. 29, 2022 and titled, “Electrochemical Cells with Multiple Separators, and Methods of Producing the Same,” the disclosure of which is hereby incorporated by reference in its entirety. In some embodiments, the interlayers described herein can include any of the properties described in U.S. Pat. No. 11,984,564 (“the '564 patent), filed Dec. 18, 2023 and titled, “Systems and Methods for Minimizing and Preventing Dendrite Formation in Electrochemical Cells,” the disclosure of which is hereby incorporated by reference in its entirety. In some embodiments, the interlayers described herein can include any of the properties described in U.S. patent application Ser. No. 18/746,845 (“the '845 application), filed Jun. 18, 2024 and titled, “Systems and Methods for Minimizing and Preventing Dendrite Formation in Electrochemical Cells,” the disclosure of which is hereby incorporated by reference in its entirety.

While embodiments described in the '597 publication, the '564 patent, and the '845 application are useful for detecting dendrites that have entered the space of the interlayer, embodiments described herein can be used to detect the presence of dendrites before the dendrites have penetrated a separator (e.g., any one of the separators disposed on either side of the interlayer) of the electrochemical cell. Interlayers described herein can also be utilized as reference electrodes. In such implementations, the relative voltage of the reference electrode can be utilized to determine a true state-of-charge of an electrochemical cell or a collection/stack of electrochemical cells. If sensed individually, reference electrodes (i.e., interlayers) of parallel electrochemical cells can be monitored to evaluate the electrochemical cells individually. Such a capability can be used to evaluate the relative health of multiple electrochemical cells arranged in a parallel stack. For example, such evaluation of electrochemical cells can be beneficial for the reuse of electrochemical cells during recycling operations.

In some embodiments, parameters can be developed from measuring voltage differences between the interlayer and at least one of the anode or the cathode throughout the course of a charge or discharge. Such parameters can include voltage curves and act as reference curves. Later, during operation, such parameters can be developed again, and the operational parameters can be compared to the initial parameters. Differences between the initial parameters and the operational parameters can be evaluated to determine whether dendrites have begun to form in the electrochemical cell. Additionally, if the values of the parameters are constant, or change too rapidly, it can be determined that the connections are either shorted or open circuit.

Electrodes described herein can include semi-solid electrodes. Semi-solid electrodes described herein can be made: (i) thicker (e.g., greater than 100-m-up to 2,000 μm or even greater) due to the reduced tortuosity and higher electronic conductivity of the semi-solid electrode, (ii) with higher loadings of active materials, and (iii) with a simplified manufacturing process utilizing less equipment. These relatively thick semi-solid electrodes decrease the volume, mass and cost contributions of inactive components with respect to active components, thereby enhancing the commercial appeal of batteries made with the semi-solid electrodes. In some embodiments, the semi-solid electrodes described herein are binderless and/or do not use binders that are used in conventional battery manufacturing. Instead, the volume of the electrode normally occupied by binders in conventional electrodes, is now occupied by: 1) electrolyte, which has the effect of decreasing tortuosity and increasing the total salt available for ion diffusion, thereby countering the salt depletion effects typical of thick conventional electrodes when used at high rate, 2) active material, which has the effect of increasing the charge capacity of the battery, or 3) conductive additive, which has the effect of increasing the electronic conductivity of the electrode, thereby countering the high internal impedance of thick conventional electrodes. The reduced tortuosity and a higher electronic conductivity of the semi-solid electrodes described herein, results in superior rate capability and charge capacity of electrochemical cells formed from the semi-solid electrodes. Since the semi-solid electrodes described herein, can be made substantially thicker than conventional electrodes, the ratio of active materials (i.e., the semi-solid cathode and/or anode) to inactive materials (i.e., the current collector and separator) can be much higher in a battery formed from electrochemical cell stacks that include semi-solid electrodes relative to a similar battery formed form electrochemical cell stacks that include conventional electrodes. This substantially increases the overall charge capacity and energy density of a battery that includes the semi-solid electrodes described herein.

In some embodiments, the electrode materials described herein can be a flowable semi-solid or condensed liquid composition. In some embodiments, the electrode materials described herein can be binderless or substantially free of binder. A flowable semi-solid electrode can include a suspension of an electrochemically active material (anodic or cathodic particles or particulates), and optionally an electronically conductive material (e.g., carbon) in a non-aqueous liquid electrolyte. Said another way, the active electrode particles and conductive particles are co-suspended in an electrolyte to produce a semi-solid electrode. Examples of battery architectures utilizing semi-solid suspensions are described in International Patent Publication No. WO 2012/024499, entitled “Stationary, Fluid Redox Electrode,” and International Patent Publication No. WO 2012/088442, entitled “Semi-Solid Filled Battery and Method of Manufacture,” the entire disclosures of which are hereby incorporated by reference.

As used in this specification, the singular forms “a,” “an,” and “the” include plural referents unless the context clearly dictates otherwise. Thus, for example, the term “a member” is intended to mean a single member or a combination of members, “a material” is intended to mean one or more materials, or a combination thereof.

The term “substantially” when used in connection with “cylindrical,” “linear,” and/or other geometric relationships is intended to convey that the structure so defined is nominally cylindrical, linear or the like. As one example, a portion of a support member that is described as being “substantially linear” is intended to convey that, although linearity of the portion is desirable, some non-linearity can occur in a “substantially linear” portion. Such non-linearity can result from manufacturing tolerances, or other practical considerations (such as, for example, the pressure or force applied to the support member). Thus, a geometric construction modified by the term “substantially” includes such geometric properties within a tolerance of plus or minus 5% of the stated geometric construction. For example, a “substantially linear” portion is a portion that defines an axis or center line that is within plus or minus 5% of being linear.

As used herein, the term “set” and “plurality” can refer to multiple features or a singular feature with multiple parts. For example, when referring to a set of electrodes, the set of electrodes can be considered as one electrode with multiple portions, or the set of electrodes can be considered as multiple, distinct electrodes. Additionally, for example, when referring to a plurality of electrochemical cells, the plurality of electrochemical cells can be considered as multiple, distinct electrochemical cells or as one electrochemical cell with multiple portions. Thus, a set of portions or a plurality of portions may include multiple portions that are either continuous or discontinuous from each other. A plurality of particles or a plurality of materials can also be fabricated from multiple items that are produced separately and are later joined together (e.g., via mixing, an adhesive, or any suitable method).

As used herein, the term “semi-solid” refers to a material that is a mixture of liquid and solid phases, for example, such as a particle suspension, a slurry, a colloidal suspension, an emulsion, a gel, or a micelle.

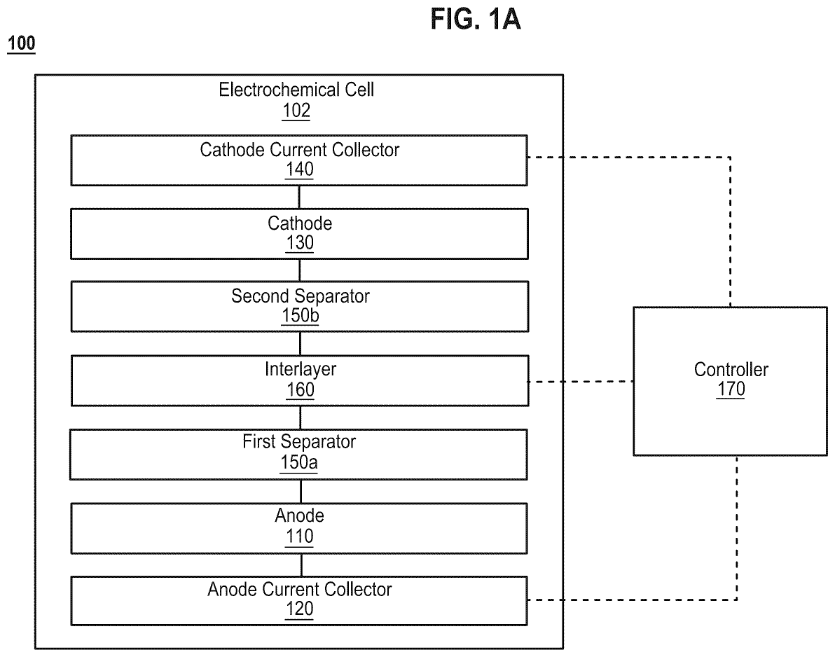

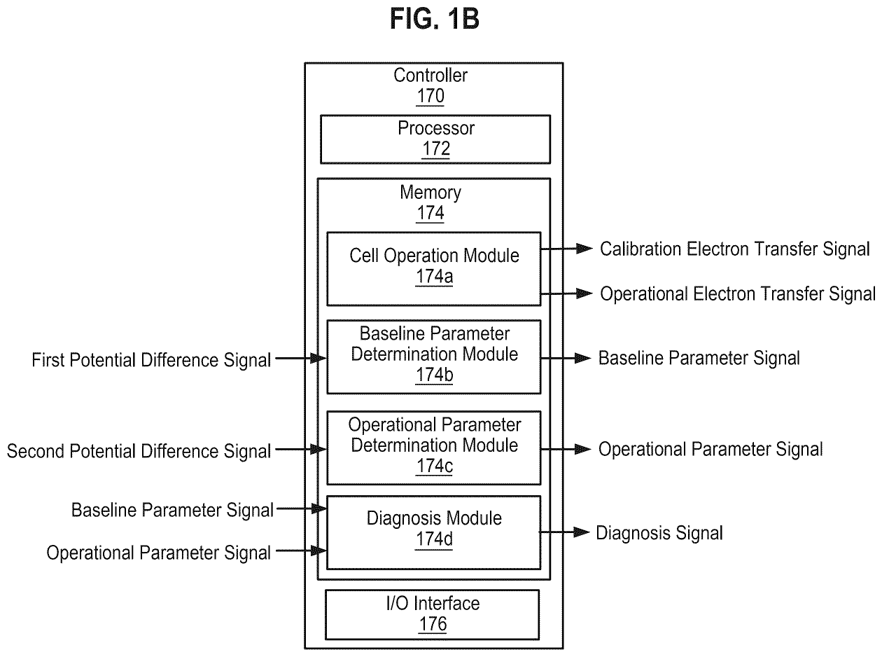

FIGS. 1A-1B are block diagrams of an electrochemical cell system 100 and components thereof, according to an embodiment. FIG. 1A shows the electrochemical cell system 100. As shown, the electrochemical cell system 100 includes an electrochemical cell 102 and a controller 170. The electrochemical cell 102 (also referred to as “cell 102”) includes an anode 110 disposed on an anode current collector 120, a cathode 130 disposed on a cathode current collector 140, a first separator 150a disposed on the anode 110, a second separator 150b disposed on the cathode 130, and an interlayer 160 disposed between the first separator 150a and the second separator 150b (collectively referred to as “separators 150”). The controller 170 can be communicatively and/or physically coupled to the anode current collector 120, the cathode current collector 140, and/or the interlayer 160. In some embodiments, the controller 170 can be coupled to the anode current collector 120, the cathode current collector 140, and/or the interlayer 160 via one or more tabs coupled to the anode current collector 120, the cathode current collector 140, and/or the interlayer 160.

In some embodiments, the anode 110 and/or the cathode 130 can include at least about 0.1%, at least about 0.2%, at least about 0.3%, at least about 0.4%, at least about 0.5%, at least about 0.6%, at least about 0.7%, at least about 0.8%, at least about 0.9%, at least about 1%, at least about 2%, at least about 3%, at least about 4%, at least about 5%, at least about 6%, at least about 7%, at least about 8%, at least about 9%, at least about 10%, at least about 11%, at least about 12%, at least about 13%, at least about 14%, at least about 15%, at least about 16%, at least about 17%, at least about 18%, at least about 19%, at least about 20%, at least about 21%, at least about 22%, at least about 23%, or at least about 24% by volume of liquid electrolyte solution. In some embodiments, the anode 110 and/or the cathode 130 can include no more than about 25%, no more than about 24%, no more than about 23%, no more than about 22%, no more than about 21%, no more than about 20%, no more than about 19%, no more than about 18%, no more than about 17%, no more than about 16%, no more than about 15%, no more than about 14%, no more than about 13%, no more than about 12%, no more than about 11%, no more than about 10%, no more than about 9%, no more than about 8%, no more than about 7%, no more than about 6%, no more than about 5%, no more than about 4%, no more than about 3%, no more than about 2%, no more than about 1%, no more than about 0.9%, no more than about 0.8%, no more than about 0.7%, no more than about 0.6%, no more than about 0.5%, no more than about 0.4%, no more than about 0.3%, or no more than about 0.2% by volume of liquid electrolyte solution.

Combinations of the above-referenced volumetric percentages of liquid electrolyte solution in the anode 110 and/or the cathode 130 are also possible (e.g., at least about 0.1% and no more than about 25%, or at least about 5% and no more than about 10%), inclusive of all values and ranges therebetween. In some embodiments, the anode 110 and/or the cathode 130 can include about 0.1%, about 0.2%, about 0.3%, about 0.4%, about 0.5%, about 0.6%, about 0.7%, about 0.8%, about 0.9%, about 1%, about 2%, about 3%, about 4%, about 5%, about 6%, about 7%, about 8%, about 9%, about 10%, about 11%, about 12%, about 13%, about 14%, about 15%, about 16%, about 17%, about 18%, about 19%, about 20%, about 21%, about 22%, about 23%, about 24%, or about 25% by volume of liquid electrolyte solution.

In some embodiments, the anode current collector 120 and/or the cathode current collector 140 can include copper, aluminum, titanium, or other metals that do not form alloys or intermetallic compounds with lithium, carbon, and/or coatings including such materials disposed on another conductor. In some embodiments, the anode current collector 120 and/or the cathode current collector 140 can have a thickness of at least about 1 μm, at least about 5 μm, at least about 10 μm, at least about 15 μm, at least about 20 μm, at least about 25 μm, at least about 30 μm, at least about 35 μm, at least about 40 μm, or at least about 45 μm. In some embodiments, the anode current collector 120 and/or the cathode current collector 140 can have a thickness of no more than about 50 μm, no more than about 45 μm, no more than about 40 μm, no more than about 35 μm, no more than about 30 μm, no more than about 25 μm, no more than about 20 μm, no more than about 15 μm, no more than about 10 μm, or no more than about 5 μm. Combinations of the above-referenced thicknesses of the anode current collector 120 and/or the cathode current collector 140 are also possible (e.g., at least about 1 μm and no more than about 50 μm, or at least about 10 μm and no more than about 30 μm), inclusive of all values and ranges therebetween. In some embodiments, the anode current collector 120 and/or the cathode current collector 140 can have a thickness of about 1 μm, about 5 μm, about 10 μm, about 15 μm, about 20 μm, about 25 μm, about 30 μm, about 35 μm, about 40 μm, about 45 μm, or about 50 μm.

In some embodiments, the anode 110 can include a first electrolyte and the cathode 130 can include a second electrolyte. In other words, the anode 110 can include an anolyte and the cathode 130 can include a catholyte. In some embodiments, the electrochemical cell 102 can include an anolyte disposed on the anode side of the separators 150. In some embodiments, the electrochemical cell 102 can include a catholyte disposed on the cathode side of the separators 150. In some embodiments, the electrochemical cell 102 can include a selectively permeable membrane. In some embodiments, the selectively permeable membrane can be disposed between the first separator 150a and the second separator 150b. Electrochemical cells with anolytes, catholytes, and/or selectively permeable membranes are described in U.S. Pat. No. 10,734,672 (“the '672 patent”), filed Jan. 8, 2019, and titled, “Electrochemical Cells Including Selectively Permeable Membranes, Systems and Methods of Manufacturing the Same,” the disclosure of which is hereby incorporated by reference in its entirety.

As shown, the first separator 150a is disposed on the anode 110 while the second separator 150b is disposed on the cathode 130. In some embodiments, the separators 150 can be disposed on their respective electrodes during production of the electrochemical cell 102. In some embodiments, the first separator 150a and/or the second separator 150b can include polyethylene, polypropylene, high density polyethylene, polyethylene terephthalate, polystyrene, a thermosetting polymer, hard carbon, a thermosetting resin, a polyimide, a ceramic coated separator, an inorganic separator, cellulose, glass fiber, a polyethylenoxide (PEO) polymer in which a lithium salt is complexed to provide lithium conductivity, NAFION™ membranes which are proton conductors, or any other suitable separator material, or combinations thereof. In some embodiments, the first separator 150a can include the same material as the second separator 150b. In some embodiments, the first separator 150a can include a different material from the second separator 150b.

In some embodiments, the first separator 150a and/or the second separator 150b can have a porosity of at least about 10%, at least about 15%, at least about 20%, at least about 25%, at least about 30%, at least about 35%, at least about 40%, at least about 45%, at least about 50%, at least about 55%, at least about 60%, at least about 65%, at least about 70%, at least about 75%, at least about 80%, at least about 85%, or at least about 90%. In some embodiments, the first separator 150a and/or the second separator 150b can have a porosity of no more than about 95%, no more than about 90%, no more than about 85%, no more than about 80%, no more than about 75%, no more than about 70%, no more than about 65%, no more than about 60%, no more than about 55%, no more than about 50%, no more than about 45%, no more than about 40%, no more than about 35%, no more than about 30%, no more than about 25%, no more than about 20%, or no more than about 15%.

Combinations of the above-referenced porosity percentages of the first separator 150a and/or the second separator 150b are also possible (e.g., at least about 10% and no more than about 95% or at least about 20% and no more than about 40%), inclusive of all values and ranges therebetween. In some embodiments, the first separator 150a and/or the second separator 150b can have a porosity of about 10%, about 15%, about 20%, about 25%, about 30%, about 35%, about 40%, about 45%, about 50%, about 55%, about 60%, about 65%, about 70%, about 75%, about 80%, about 85%, about 90%, or about 95%, inclusive.

In some embodiments, the first separator 150a can have a different porosity from the second separator 150b. In some embodiments, the porosities of the first separator 150a and the second separator 150b can be selected based on the difference between the anolyte and the catholyte. For example, if the catholyte has a higher vapor pressure and faster evaporation properties than the anolyte, then the second separator 150b can have a lower porosity than the first separator 150a. The lower porosity of the second separator 150b can at least partially prevent the catholyte from evaporating during production.

In some embodiments, the first separator 150a can include a different material from the second separator 150b. In some embodiments, the materials of the first separator 150a and the second separator 150b can be selected to facilitate wettability of the first separator 150a with the anolyte and the second separator 150b with the catholyte. For example, an ethylene carbonate/propylene carbonate-based catholyte can wet a polyethylene separator better than a polyimide separator, based on the molecular properties of the materials. An ethylene carbonate/dimethyl carbonate-based anolyte can wet a polyimide separator better than a polyethylene separator. A full wetting of the first separator 150a and the second separator 150b can give way to better transport of electroactive species via the separators 150. This transport can be facilitated particularly well when the first separator 150a physically contacts the second separator 150b. In some embodiments, the first separator 150a can include polyethylene and the second separator 150b can include a ceramic powder, while the interlayer 160 includes a carbonaceous material. In some embodiments, the first separator 150a can include a ceramic powder and the second separator 150b can include polyethylene, while the interlayer 160 includes a carbonaceous material.

As shown, the electrochemical cell 102 includes two separators 150. In some embodiments, the electrochemical cell 102 can include 3, 4, 5, 6, 7, 8, 9, 10, or more than about 10 separators 150 with interlayers 160 interposed therebetween. In some embodiments, a layer of liquid electrolyte (not shown) can be disposed between the first separator 150a and the second separator 150b. A layer of liquid electrolyte can promote better adhesion between the separators 150. As shown, the electrochemical cell 102 includes one interlayer 160. In some embodiments, the electrochemical cell 102 can include 2, 3, 4, 5, 6, 7, 8, 9, 10, or more than about 10 interlayers 160.

In some embodiments, the first separator 150a and/or the second separator 150b can have a thickness of at least about 0.5 μm, at least about 1 μm, at least about 2 μm, at least about 3 μm, at least about 4 μm, at least about 5 μm, at least about 6 μm, at least about 7 μm, at least about 8 μm, at least about 9 μm, at least about 10 μm, at least about 15 μm, at least about 20 μm, or at least about 25 μm. In some embodiments, the first separator 150a and/or the second separator 150b can have a thickness of no more than about 30 μm, no more than about 25 μm, no more than about 20 μm, no more than about 15 μm, no more than about 10 μm, no more than about 9 μm, no more than about 8 μm, no more than about 7 μm, no more than about 6 μm, no more than about 5 μm, no more than about 4 μm, no more than about 3 μm, no more than about 2 μm, or no more than about 1 μm. Combinations of the above-referenced thicknesses of the first separator 150a and/or the second separator 150b are also possible (e.g., at least about 0.5 μm and no more than about 30 μm or at least about 5 μm and no more than about 20 μm), inclusive of all values and ranges therebetween. In some embodiments, the first separator 150a and/or the second separator 150b can have a thickness of about 0.5 μm, about 1 μm, about 2 μm, about 3 μm, about 4 μm, about 5 μm, about 6 μm, about 7 μm, about 8 μm, about 9 μm, about 10 μm, about 15 μm, about 20 μm, about 25 μm, or about 30 μm. In some embodiments, the first separator 150a can have a thickness the same or substantially similar to the thickness of the second separator 150b. In some embodiments, the first separator 150a can have a thickness greater or less than a thickness of the second separator 150b.

In some embodiments, the first separator 150a, the second separator 150b, and the interlayer 160 can form a film. In some embodiments, the film can have a total thickness of at least about 5 μm, at least about 6 μm, at least about 7 μm, at least about 8 μm, at least about 9 μm, at least about 10 μm, at least about 15 μm, at least about 20 μm, at least about 25 μm, at least about 30 μm, at least about 35 μm, at least about 40 μm, or at least about 45 μm. In some embodiments, the film can have a total thickness of no more than about 50 μm, no more than about 45 μm, no more than about 40 μm, no more than about 35 μm, no more than about 30 μm, no more than about 25 μm, no more than about 20 μm, no more than about 15 μm, no more than about 10 μm, no more than about 9 μm, no more than about 8 μm, no more than about 7 μm, or no more than about 6 μm. Combinations of the above-referenced thicknesses are also possible (e.g., at least about 5 μm and no more than about 50 μm, or at least about 10 μm and no more than about 40 μm), inclusive of all values and ranges therebetween. In some embodiments, the film can have a total thickness of about 5 μm, about 6 μm, about 7 μm, about 8 μm, about 9 μm, about 10 μm, about 15 μm, about 20 μm, about 25 μm, about 30 μm, about 35 μm, about 40 μm, about 45 μm, or about 50 μm.

In some embodiments, the first separator 150a and/or the second separator 150b can include a solid-state electrolyte sheet. In some embodiments, the solid-state electrolyte sheet can replace the first separator 150a and/or the second separator 150b. In some embodiments, the first separator 150a and/or the second separator 150b can be made with a separator film. In some embodiments, the first separator 150a and/or the second separator 150b can include a coating polymer, a spray polymer, and/or a print polymer. In some embodiments, the first separator 150a and/or the second separator 150b can include a ceramic powder. In some embodiments, the first separator 150a and/or the second separator 150b can be absent of a ceramic powder. In some embodiments, the first separator 150a and/or the second separator 150b can include a ceramic with a liquid electrolyte and/or a solid-state electrolyte.

In some embodiments, the interlayer 160 can include a conductive layer. In some embodiments, the interlayer 160 can include a liquid electrolyte. In some embodiments, the interlayer 160 can include a solid-state electrolyte. In some embodiments, the interlayer 160 can include KETJENBLACK® (electroconductive carbon black), AA-stacked graphene, AB-stacked graphene, carbon, hard carbon, soft carbon, graphite, lithium iron phosphate (LFP), lithium manganese iron phosphate (LMFP), lithium manganese oxide (LMO), LiNiO₂ (LNO), nickel manganese cobalt (NMC), lithium nickel manganese oxide (LNMO), lithium cobalt oxide (LCO), Iron (III) fluoride (FeF₃), sulfur, vanadium (V) oxide (V₂O₅), bismuth trifluoride (BiF₃), iron (IV) sulfate (FeS₂), or any combination thereof. In some embodiments, the interlayer 160 can create a physical block that prevents vertical growth of the dendrite, such that the dendrite is forced to grow horizontally.

In some embodiments, the interlayer 160 can include an intercalate cathode (e.g., LMOP, LNO, NMC, LFP, LNMO, LCO, and/or LMFP). In some embodiments, the interlayer 160 can include a convertible cathode (e.g., FeF₃, sulfur, V₂O₅, BiF₃, FeS₂). In some embodiments, the interlayer 160 can include a high voltage bearable anode. In some embodiments, the interlayer 160 can include a traditional anode (e.g., hard carbon, graphite, and/or silicon). In some embodiments, the interlayer 160 can include a metal. In some embodiments, the interlayer 160 can include a metal alloy. In some embodiments, the metal alloy can include lithium, tin, aluminum, silver, and/or copper. In some embodiments, the interlayer 160 can include a metal oxide. In some embodiments, the metal oxide can include silicon oxide (SiO), zinc oxide (ZnO), copper oxide (Cu₂O), lithium titanate (LTO), and/or titanium (IV) oxide (TiO₂). In some embodiments, the interlayer 160 can include a semi-solid electrode. In some embodiments, the interlayer 160 can include a coating, a spray, and/or a print polymer. In some embodiments, the interlayer 160 can include a ceramic powder. In some embodiments, the interlayer 160 can include a premade film with a solid-state electrolyte.

In some embodiments, the interlayer 160 can include an electronically active material. In some embodiments, the interlayer 160 can include conductive materials. In some embodiments, the interlayer 160 can include allotropes of carbon including activated carbon, hard carbon, soft carbon, KETJENBLACK®, carbon black, graphitic carbon, carbon fibers, carbon microfibers, vapor-grown carbon fibers (VGCF), fullerenic carbons including “buckyballs,” carbon nanotubes (CNTs), multiwall carbon nanotubes (MWNTs), single wall carbon nanotubes (SWNTs), graphene, graphene sheets, aggregates of graphene sheets, and materials comprising fullerenic fragments, or any combination thereof.

In some embodiments, the interlayer 160 can include a solid-state electrolyte material and/or electrode material. In some embodiments, the solid-state electrolyte material (also referred to as “solid-state electrolyte” or “SSE”) can include an oxide-based electrolyte. In some embodiments, the solid-state electrolyte material can include lithium lanthanum zirconium oxide (LLZO), Li_{1.3}Al_{0.3}Ti_{1.7}(PO₄)₃ (LATP), lithium phosphorus oxynitride (LiPON), li-ion conducting solid-state electrolyte ceramics (LLTO), and/or Li₃BO₃—Li₂SO₄—Li₂CO₃ (LiBSCO). In some embodiments, the solid-state electrolyte material can include one or more oxide-based solid electrolyte materials including a garnet structure, a perovskite structure, a phosphate-based Lithium Super Ionic Conductor (LISICON) structure, a glass structure such as La_{0.51}Li_{0.34}TiO_{2.94}, Li_{1.3}Al_{0.3}Ti_{1.7}(PO₄)₃, Li_{1.4}Al_{0.4}Ti_{1.6}(PO₄)₃, Li₇La₃Zr₂O₁₂, Li_{6.66}La₃Zr_{1.6}Ta_{0.4}O_{12.9} (LLZO), 50Li₄SiO₄·50Li₃BO₃, Li_{2.9}PO_{3.3}N_{0.46} (lithium phosphorousoxynitride, LiPON), Li_{3.6}Si_{0.6}P_{0.4}O₄, Li₃BN₂, Li₃BO₃—Li₂SO₄, and/or sulfide containing solid electrolyte materials including a thio-LISICON structure, a glassy structure and a glass-ceramic structure such as Li_{1.07}Al_{0.69}Ti_{1.46}(PO₄)₃, Li_{1.5}Al_{0.5}Ge_{1.5}(PO₄)₃, Li₁₀GeP₂S₁₂ (LGPS), 30Li₂S·₂₆B₂S₃·44LiI, 63Li₂S·36SiS₂·1Li₃PO₄, 57Li₂S·38SiS₂·5Li₄SiO₄, 70Li₂S·30P₂S₅, 50Li₂S·50GeS₂, Li₇P₃S₁₁, Li_{3.25}P_{0.95}S₄, and Li_{9.54}Si_{1.74}P_{1.44}S_{11.7}Cl_{0.3}, and/or closo-type complex hydride solid electrolyte, LiBH₄—LiI, LiBH₄—LiNH₂, LiBH₄—P₂S₅, Li(CB_{X}H_{X+1})—LiI, Li(CB₉H₁₀)— and/or LiI. In some embodiments, the solid-state electrolyte material can be sulfide-based. In some embodiments, the solid-state electrolyte can include lithium phosphorus sulfide (LPS), Li₁₀GeP₂S₁₂ (LGPS), lithium tin phosphorus sulfide (LSPS), and/or Li_{5.5}PS_{4.5}Cl_{1.5} (LPSCI). In some embodiments, the solid-state electrolyte material can include a complex hydride solid electrolyte. In some embodiments, the solid-state electrolyte material can include LiBH₄—LiI and/or LiBH₄—P₂S₅.

In some embodiments, when the interlayer 160 includes a solid-state electrolyte, the interlayer 160 can have a porosity of at least about 0%, at least about 5%, at least about 10%, at least about 15%, at least about 20%, at least about 25%, at least about 30%, at least about 35%, at least about 40%, at least about 45%, at least about 50%, at least about 55%, at least about 60%, at least about 65%, at least about 70%, at least about 75%, at least about 80%, at least about 85%, or at least about 90%. In some embodiments, when the interlayer 160 includes a solid-state electrolyte, the interlayer 160 can have a porosity of no more than about 95%, no more than about 90%, no more than about 85%, no more than about 80%, no more than about 75%, no more than about 70%, no more than about 65%, no more than about 60%, no more than about 55%, no more than about 50%, no more than about 45%, no more than about 40%, no more than about 35%, no more than about 30%, no more than about 25%, no more than about 20%, no more than about 15%, no more than about 10%, or no more than about 5%. Combinations of the above-referenced porosities are also possible (e.g., at least about 0% and no more than about 95%, or at least about 10% and no more than about 50%), inclusive of all values and ranges therebetween. In some embodiments, when the interlayer includes a solid-state electrolyte, the interlayer 160 can have a porosity of about 0%, about 5%, about 10%, about 15%, about 20%, about 25%, about 30%, about 35%, about 40%, about 45%, about 50%, about 55%, about 60%, about 65%, about 70%, about 75%, about 80%, about 85%, about 90%, or about 95%.

In some embodiments, when the interlayer 160 includes a liquid electrolyte, the interlayer 160 can have a porosity of at least about 10%, at least about 15%, at least about 20%, at least about 25%, at least about 30%, at least about 35%, at least about 40%, at least about 45%, at least about 50%, at least about 55%, at least about 60%, at least about 65%, at least about 70%, at least about 75%, at least about 80%, at least about 85%, or at least about 90%. In some embodiments, when the interlayer 160 includes a liquid electrolyte, the interlayer 160 can have a porosity of no more than about 95%, no more than about 90%, no more than about 85%, no more than about 80%, no more than about 75%, no more than about 70%, no more than about 65%, no more than about 60%, no more than about 55%, no more than about 50%, no more than about 45%, no more than about 40%, no more than about 35%, no more than about 30%, no more than about 25%, no more than about 20%, or no more than about 15%. Combinations of the above-referenced porosities are also possible (e.g., at least about 10% and no more than about 95%, or at least about 15% and no more than about 50%), inclusive of all values and ranges therebetween. In some embodiments, when the interlayer includes a liquid electrolyte, the interlayer 160 can have a porosity of about 10%, about 15%, about 20%, about 25%, about 30%, about 35%, about 40%, about 45%, about 50%, about 55%, about 60%, about 65%, about 70%, about 75%, about 80%, about 85%, about 90%, or about 95%.

In some embodiments, the interlayer 160 can be pre-coated onto the first separator 150a and/or the second separator 150b. In some embodiments, the interlayer 160 can aid in identifying a contamination amount of lithium or another metal via a battery management system (BMS). The BMS can then add more voltage and current to the interlayer 160 to dissolve the contamination. The BMS can keep the state of charge (SOC) of the interlayer 160 between a lower bound (e.g., about 10%, about 15%, about 20%, about 25%, about 30%, about 35%, or about 40%, inclusive of all values and ranges therebetween) and an upper bound (e.g., about 60%, about 65%, about 70%, about 75%, about 80%, about 85%, or about 90%, inclusive of all values and ranges therebetween). Keeping the interlayer 160 between a lower bound and an upper bound of voltage can aid in diminishing dendrite formation while the electrochemical cell 102 is not in use (i.e., via addition of voltage and/or current). In some embodiments, the interlayer 160 can include a tab (not shown) that can be used to monitor the voltage of the interlayer 160, for example, while the electrochemical cell 102 is hot pressed (e.g., via a two-sided hot press or a four-sided hot press with a jelly roll design to fit into a prismatic can).

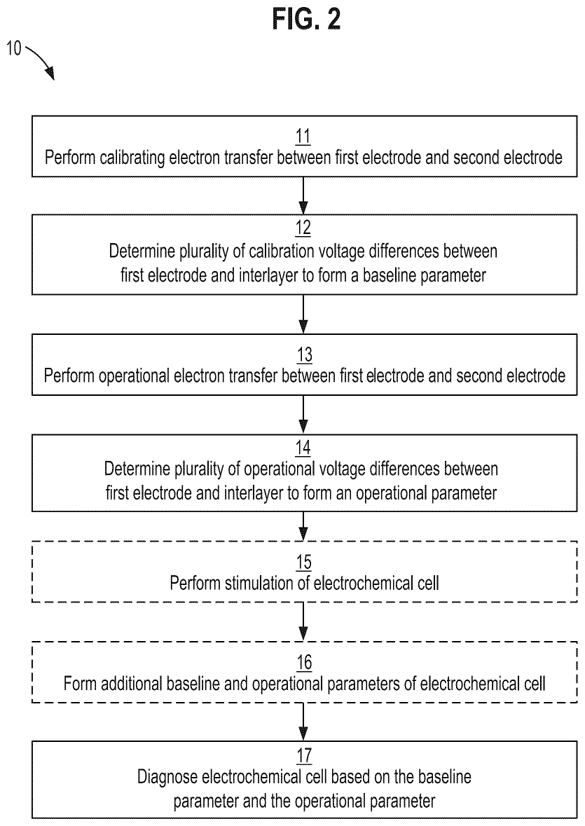

The controller 170 is configured to control operations of the electrochemical cell 102. For example, in some embodiments, the controller 170 may be configured to transmit various operational or calibration signals to the electrochemical cell 102, receive various sensing signals from the cell 102, and/or analyze the received signals to diagnose the cell 102 (e.g., monitor dendrite formation and connectivity issues). While described herein as being configured to perform certain operations, the controller 170 can be configured to perform any operations as described with respect to the method 10 shown in FIG. 2, or any other method described herein. In some embodiments, the controller 170 is configured to perform a calibrating electrical energy transfer between a first electrode (e.g., the anode 110 or cathode 130) and a second electrode (e.g., the anode 110 or cathode 130) of the electrochemical cell 102. In some implementations, the calibrating electrical energy transfer includes an initial charge of the electrochemical cell 102. In some implementations, the calibrating electrical energy transfer includes an initial discharge of the electrochemical cell 102. In some embodiments, the calibration of the signal can be based on data or functions stored in memory of the controller 170 (e.g., memory 174 shown in FIG. 1B) for the use of diagnosis of dendrite formation over time.

In some embodiments, the controller 170 is configured to determine a plurality of calibration voltage differences between the first electrode (e.g., the anode 110 or the cathode 130) and the interlayer 160. In some embodiments, the controller 170 is configured to determine a baseline parameter based on the calibration voltage differences. The baseline parameter may include an equation, an algorithm, a table, a plot, a curve, a digital filter, an analog filter, or any other suitable baseline parameter, or any suitable combination thereof, that relates to the baseline charge/discharge performance of the electrochemical cell 102. In some implementations, the baseline parameter is described by the equation:

$${v}_{t} = Δ V ( 1 - {e}^{t / τ} )$$

where vₜ is a time-dependent voltage difference between the first electrode and the interlayer, ΔV is an applied voltage difference between the first electrode and the interlayer, t is time, and τ is an RC time constant.

The controller 170 may be configured to perform or cause an operational electrical energy transfer between the first electrode (e.g., anode 110) and the second electrode (e.g., cathode 130), or vice versa. The operational electrical energy transfer may include a subsequent charge of one or more electrodes of the electrochemical cell 102, for example, when the calibrating electrical energy transfer includes an initial charge of one or more electrodes (e.g., anode 110 and/or cathode 130) of the electrochemical cell 102, or the operational electrical energy transfer may include a subsequent discharge of one or more electrodes (e.g., anode 110 and/or cathode 130) of the electrochemical cell 102, for example, when the calibrating electrical energy transfer includes an initial discharge of one or more electrodes (e.g., anode 110 and/or cathode 130) of the electrochemical cell 102. In some embodiments, the baseline electrical energy transfer and the operational electrical energy transfer are executed via a constant voltage source. In some embodiments, the first electrical energy transfer and the subsequent electrical energy transfers are executed via a variable frequency voltage source. In some embodiments, the first electrical energy transfer and the subsequent electrical energy transfers can be executed via a switched load, relative to a passive device.

The controller 170 may also be configured to determine a plurality of operational voltage differences between the first electrode (e.g., the anode 110 or the cathode 130) and the interlayer 160. The controller 170 may also be configured to determine an operational parameter related to operation of the electrochemical cell 102 based on the operational voltage differences. The operational parameter may also include an equation, an algorithm, a table, a plot, a curve, a digital filter, an analog filter, or any other suitable baseline parameter, or any suitable combination thereof. In some embodiments, the controller 170 can employ artificial intelligence (AI), AI training, machine learning, deep learning (e.g., neural networks), and/or similar technologies that relate to the operational charge/discharge performance of the electrochemical cell 102.

The controller 170 may be configured to diagnose a performance issue with the electrochemical cell 102 based on the baseline parameter and the operational parameter. For example, if the electrochemical cell 102 is under normal operating conditions, the operational parameter may be substantially similar to the baseline parameter (e.g., within +10% of the baseline parameter, such as baseline parameter curve). However, a difference in the operational parameter relative to the baseline parameter which is outside normal error bounds may indicate an issue with electrochemical cell 102 performance or the presence of a dendrite (e.g., during and/or after forming). In some implementations, the difference between the baseline parameter and the operational parameter may be characterized by a difference between the computed RC time constant of the baseline parameter and a computed RC time constant of the operational parameter. In some implementations, the controller 170 may be configured to diagnose the performance issue with the electrochemical cell 102 by evaluating an average deviation between the baseline parameter and the operational parameter. In some implementations, the performance issue includes a lack of electrical connectivity between a testing circuit and the interlayer 160.

In some implementations, the calibrating electrical energy transfer is a first calibrating electrical energy transfer, the plurality of calibration voltage differences are a first plurality of calibration voltage differences (also referred to as “calibrating voltage differences”), the baseline parameter is a first baseline parameter, the operational electrical energy transfer is a first operational electrical energy transfer, the plurality of operational voltage differences are a first plurality of operational voltage differences, and the operational parameter is a first operational parameter. In such implementations, the controller 170 may be configured to cause a first stimulation of the interlayer 160 via at least one of a pullup (e.g., a pullup resistor disposed between the interlayer 160 and the cathode 130) or a pulldown (e.g., a pulldown resistor disposed between the interlayer 160 and the anode 110), for example, pullup or pulldown a voltage of the interlayer 160. The controller 170 may be configured to perform a second calibrating electrical energy transfer between the first electrode and the second electrode (e.g., between the anode 110 and the cathode 130, or vice versa), and determine a second plurality of calibration voltage differences between the first electrode (e.g., anode 110 or cathode 130) and the interlayer 160. The controller 170 may also determine a second baseline parameter based on the second plurality of calibration voltage differences. The controller 170 may also be configured to perform a second stimulation, that may be the same or substantially similar to the first stimulation, of the interlayer 160. In some embodiments, stimulation of the reference electrode can be by any means suitable for the use of diagnosing the response characteristic, as described above and with reference to the '597 publication, the '564 patent, and the '845 application.

The controller 170 may also be configured to perform a second operational electrical energy transfer between the first electrode and the second electrode (e.g., anode 110 and cathode 130, or vice versa), and determine a plurality of second operational voltage differences between the first electrode (e.g., the anode 110 or the cathode 130) and the interlayer 160. The controller 170 may determine a second operational parameter based on the plurality of second operational voltage differences, and based on a difference between the second baseline parameter and the second operational parameter, diagnose a performance issue with the electrochemical cell 102. In some implementations, the performance issue includes at least one of a connection issue in the electrochemical cell 102 or a dendrite, for example, formed in or on the first electrode (e.g., in the anode 110).

In some implementations, the controller 170 may also be configured to cause changing of a resistance of a circuit connecting the first electrode (e.g., the anode 110 or the cathode 130) to the interlayer 160. The controller 170 may be configured to cause a second calibrating electrical energy transfer between the first electrode and the second electrode (e.g., between the anode 110 and the cathode 130, or vice versa), and determine a second plurality of calibration voltage differences between the first electrode (e.g., the anode 110 or the cathode 130) and the interlayer 160. The controller 170 may be configured to determine a second baseline parameter based on the second plurality of calibration voltage differences. The controller 170 may cause a second stimulation to be performed on the interlayer 160, which may be the same or substantially similar to the first stimulation. The controller 170 may also be configured to cause a second operational electrical energy transfer between the first electrode and the second electrode, and determine a plurality of second operational voltage differences between the first electrode (e.g., the anode 110 or the cathode 130) and the interlayer 160. The controller 170 may be configured to determine a second operational parameter, for example, based on the plurality of second operational voltage differences, and based on a difference between the second baseline parameter and the second operational parameter, diagnose a performance issue with the electrochemical cell 102 (i.e., diagnose performance issue based on difference between second baseline parameter and second operational parameter). These actions are not limited to long term connection and signal stimulation, as they can be performed at any frequency or duty cycle as is suitable for diagnosis of the electrochemical cell system 100. Data collection and evaluation are also not limited to voltage threshold and time base measurements. Measurements and evaluations can be performed based on frequency domain, a curve, AI, or any other suitable method or parameter.

FIG. 1B is a block diagram of the controller 170 of FIG. 1A, for example, showing further details of the controller 170. While FIG. 1B illustrates a particular embodiment of the controller 170, any other suitable controller configured to perform the operations described herein may be used. The controller 170 includes a processor 172, a memory 174, and an input/output (I/O) interface 176. The processor 172 may be implemented as a general-purpose processor, an Application Specific Integrated Circuit (ASIC), one or more Field Programmable Gate Arrays (FPGAs), a Digital Signal Processor (DSP), a group of processing components, or other suitable electronic processing components. The memory 174 [e.g., Random Access Memory (RAM), Read-Only Memory (ROM), Non-volatile RAM (NVRAM), Flash Memory, hard disk storage, etc.] stores data (e.g., operating parameter data), computer code (e.g., operating parameter filtering or processing algorithms, etc.), and/or any other information for facilitating at least some of the various processes described herein. The memory 174 may include tangible, non-transient volatile memory, or non-volatile memory. The memory 174 may include a non-transitory processor-readable medium configured to store programming logic that, when executed by the processor 172, controls the operations of the controller 170. In some arrangements, the processor 172 and the memory 174 form various processing circuits described with respect to the controller 170.

The I/O interface 176 is structured for sending and receiving data (e.g., over a communication network) from the controller 170. Accordingly, the I/O interface 176 can include any of a cellular transceiver (for cellular standards), local wireless network transceiver (for 802.11X, ZIGBEE®, BLUETOOTH®, WI-FI®, or the like), wired network interface, a combination thereof (e.g., both a cellular transceiver and a Bluetooth transceiver), and/or the like.

In some embodiments, the controller 170 may include various circuitries or modules configured to perform the operations of the controller 170. For example, as shown in FIG. 1B, the controller 170 includes a cell operation module 174a, and optionally, a baseline parameter determination module 174b, an operational parameter determination module 174c, and a diagnosis module 174d.

In some configurations, the cell operation module 174a, the baseline parameter determination module 174b, the operational parameter determination module 174c, and the diagnosis module 174d may be embodied as machine or computer-readable media (e.g., stored in the memory 174) that is executable by a processor, such as the processor 172. As described herein and amongst other uses, the machine-readable media (e.g., the memory 174) facilitates performance of certain operations of the cell operational module 174a, the baseline parameter determination module 174b, the operational parameter determination module 174c, and the diagnosis module 174d to enable reception and transmission of data. For example, the machine-readable media may be configured to provide an instruction (e.g., command, etc.), for example, to acquire data. In this regard, the machine-readable media may include programmable logic that defines the frequency of acquisition of the data (and/or transmission of the data). Thus, the computer readable media may include code, which may be written in any programming language including, but not limited to, Java or the like and any conventional procedural programming languages, such as the “C” programming language or similar programming languages. The computer readable program code may be executed on one processor (e.g., processor 172) or multiple remote processors. In the latter scenario, the remote processors may be connected to each other through any type of network (e.g., CAN bus, wireless network, etc.). In some embodiments, the processor 172 can at least partially apply neural networks and/or similar types of networks.

In some configurations, the cell operation module 174a, the baseline parameter determination module 174b, the operational parameter determination module 174c, and the diagnosis module 174d may be embodied as one or more circuitry components including, but not limited to, processing circuitry, network interfaces, peripheral devices, input devices, output devices, sensors, etc.

In some embodiments, the cell operation module 174a, the baseline parameter determination module 174b, the operational parameter determination module 174c, and the diagnosis module 174d may take the form of one or more analog circuits, electronic circuits (e.g., integrated circuits (IC), discrete circuits, system on a chip (SOCs) circuits, microcontrollers, neural networks, etc.), telecommunication circuits, hybrid circuits, and any other type of “circuit.” In this regard, the cell operation module 174a, the baseline parameter determination module 174b, the operational parameter determination module 174c, and the diagnosis module 174d may include any type of component for accomplishing or facilitating achievement of the operations described herein. For example, a circuit as described herein may include one or more transistors, logic gates (e.g., NAND, AND, NOR, OR, XOR, NOT, XNOR, etc.), resistors, multiplexers, registers, capacitors, inductors, diodes, wiring, and so on.

Thus, the cell operation module 174a, the baseline parameter determination module 174b, the operational parameter determination module 174c, and the diagnosis module 174d may also include programmable hardware devices, such as field programmable gate arrays, programmable array logic, programmable logic devices, or the like. In this regard, the cell operation module 174a, the baseline parameter determination module 174b, the operational parameter determination module 174c, and the diagnosis module 174d may include one or more memory devices for storing instructions that are executable by the processor(s) of the cell operation module 174a, the baseline parameter determination module 174b, the operational parameter determination module 174c, and/or the diagnosis module 174d. The one or more memory devices and processor(s) may have the same definition as provided below with respect to the memory 174 and the processor 172.

In the example shown, the controller 170 includes the processor 172 and the memory 174. The processor 172 and the memory 174 may be structured or configured to execute or implement the instructions, commands, and/or control processes described herein with respect to the cell operation module 174a, the baseline parameter determination module 174b, the operational parameter determination module 174c, and the diagnosis module 174d. Thus, the depicted configuration represents the aforementioned arrangement in which the cell operation module 174a, the baseline parameter determination module 174b, the operational parameter determination module 174c, and the diagnosis module 174d are embodied as machine or computer-readable media. However, as mentioned above, this illustration is not meant to be limiting as the present disclosure contemplates other embodiments, such as the aforementioned embodiment the cell operation module 174a, the baseline parameter determination module 174b, the operational parameter determination module 174c, and the diagnosis module 174d, or at least one circuit of the cell operation module 174a, the baseline parameter determination module 174b, the operational parameter determination module 174c, and the diagnosis module 174d are configured as a hardware unit. In some embodiments, the operational parameter determination module 174c can be implemented as part of a real time control method, an offline parametric method, cloud, internet of things (IoT), or any other suitable implementation or combinations thereof. In some embodiments, the operational parameter diagnosis module 174d can be implemented as part of a real time control method, an offline parametric method, cloud, IoT, or any other suitable implementation or combinations thereof. All such combinations and variations are intended to fall within the scope of the present disclosure. In some embodiments, the one or more processors may be shared by multiple circuits (e.g., the cell operation module 174a, the baseline parameter determination module 174b, the operational parameter determination module 174c, and the diagnosis module 174d) may include or otherwise share the same processor and/or device which, in some example embodiments, may execute instructions stored, or otherwise accessed, via different areas of memory (i.e., either onboard or off via cloud and/or IoT services).

The cell operation module 174a is configured to receive sensing signals, for example, electrical signals from the electrochemical cell 102, and process the sensing signals. In some embodiments, the cell operation module 174a may be configured to modify (e.g., filter, amplify, normalize, smoothen, etc.) signals received from sensor(s) operably coupled to the electrochemical cell 102, into modified signals that can be communicated by the controller 170 to a remote server. In some embodiments, the cell operation module 174a may also be configured to filter the sensing signals using hardware or software filters (e.g., low pass filters, high pass filters, band pass filters, Fourier transform filters, band stop filter, notch filter, comb filter, all pass filter, cut-off frequency filter, roll off filter, transition band filter, ripple filter, any other suitable filter, or a combination thereof) configured to filter noise from the raw sensing signals received from the sensor(s) operably coupled to the electrochemical cell 102.

In embodiments in which the controller 170 includes the baseline parameter determination module 174b, the baseline parameter determination module 174b may be configured to analyze the processed potential difference signals and determine one or more operating parameters of the electrochemical cell 102 (e.g., any of the operating parameters described herein) from the processed sensing signals. In embodiments in which the controller 170 includes the operational parameter determination module 174c, the operational parameter determination module 174c may be configured to analyze the processed potential difference signals and determine one or more operating parameters of the electrochemical cell 102 (e.g., any of the operating parameters described herein) from the processed sensing signals. In embodiments in which the controller 170 includes the diagnosis module 174d, the diagnosis module 174d may be configured to analyze the processed potential difference signals and determine one or more operating parameters of the electrochemical cell 102 (e.g., any of the operating parameters described herein) from the processed sensing signals. The I/O interface 176 is configured to generate an operating parameter signal indicative of the processed operating parameters and/or the operating parameter values obtained therefrom. The operating parameter signal may be communicated to the remote server via a communication network

The cell operation module 174a may be configured to generate a calibration transfer signal configured to cause the calibrating electrical or electrochemical transfer to be performed between the first electrode and the second electrode, as described herein. The cell operation module 174a may also be configured to generate an operational transfer signal configured to cause the operational electrical or electrochemical transfer to be performed between the first electrode and the second electrode, as described herein.

The baseline parameter determination module 174b may be configured to receive a first potential difference signal that corresponds to a plurality of calibration voltage differences determined between the first electrode (e.g., the anode 110 or the cathode 130) and the interlayer 160. The baseline parameter determination module 174b may be configured to determine a baseline parameter based on the plurality of calibration voltage differences, as described herein, and generate a baseline parameter signal indicative of the baseline parameter.

The operational parameter determination module 174c may be configured to receive a second potential difference signal that corresponds to a plurality of operational voltage differences determined between the first electrode (e.g., the anode 110 or the cathode 130) and the interlayer 160. The operational parameter determination module 174c may be configured to determine an operational parameter based on the plurality of operational voltage differences, as described herein, and generate an operational parameter signal indicative of the operational parameter.

The diagnosis module 174d may be configured to receive the baseline parameter signal and operational parameter signal, interpret the signals to determine the baseline parameter and the operational parameter, and diagnose a performance issue with the electrochemical cell 102 based on the baseline parameter and the operational parameter, as described herein.

FIG. 2 is a flow diagram of a method 10 of evaluating an electrochemical cell, according to an embodiment. As shown, the method 10 includes performing a calibrating electrical energy transfer between a first electrode and a second electrode at step 11, determining a plurality of calibration voltage differences between the first electrode and an interlayer to form a baseline parameter at step 12, performing an operational electrical energy transfer between the first electrode and the second electrode at step 13, and determining a plurality of operational voltage differences between the first electrode and the interlayer to form an operational parameter at step 14. The method 10 may optionally include performing a stimulation of the electrochemical cell at step 15 and forming additional baseline and operational parameters of the electrochemical cell at step 15. The method 10 further includes diagnosing the electrochemical cell based on the baseline parameter and the operational parameter at step 17. In some embodiments, the electrochemical cell evaluated or diagnosed in the method 10 can be the same or substantially similar to the electrochemical cell 102, as described above with reference to FIGS. 1A-1B, and/or any other electrochemical cells as described herein. Furthermore, operations and/or steps of the method 10 may be performed via the electrochemical chemical cell system 100 as described herein with respect to FIGS. 1A-1B, components thereof, and/or any other electrochemical cell systems as described herein. All such variations are envisioned herein and should be considered as part of the present disclosure.

Step 11 includes performing a calibrating electrical energy transfer between the first electrode and the second electrode (i.e., the anode and the cathode) of the electrochemical cell. In some embodiments, the calibrating electrical energy transfer can include an electron transfer, an ion transfer, and/or any other suitable electrical energy transfer. Step 11 includes transferring electricity (e.g., electrons) between the electrodes of the electrochemical cell (i.e., charging or discharging one or more of the electrodes within the electrochemical cell). The calibrating electrical energy transfer creates a basis of comparison for subsequent charges and/or discharges of one or more electrodes within the electrochemical cell, such that a comparison can be made to the initial charge/discharge to diagnose a potential problem. In some embodiments, the calibrating electrical energy transfer can be executed via a controller (e.g., the controller 170, as described above with reference to FIG. 1B).

In some embodiments, the calibrating electrical energy transfer can include charging the electrochemical cell. In some embodiments, the charging can be to at least about 10% SOC, at least about 15% SOC, at least about 20% SOC, at least about 25% SOC, at least about 30% SOC, at least about 35% SOC, at least about 40% SOC, at least about 45% SOC, at least about 50% SOC, at least about 55% SOC, at least about 60% SOC, at least about 65% SOC, at least about 70% SOC, at least about 75% SOC, at least about 80% SOC, at least about 85% SOC, at least about 90% SOC, or at least about 95% SOC. In some embodiments, the charging can be to no more than about 100% SOC, no more than about 95% SOC, no more than about 90% SOC, no more than about 85% SOC, no more than about 80% SOC, no more than about 75% SOC, no more than about 70% SOC, no more than about 65% SOC, no more than about 60% SOC, no more than about 55% SOC, no more than about 50% SOC, no more than about 45% SOC, no more than about 40% SOC, no more than about 35% SOC, no more than about 30% SOC, no more than about 25% SOC, no more than about 20% SOC, or no more than about 15% SOC. Combinations of the above-referenced SOC values are also possible (e.g., at least about 10% and no more than about 100%, or at least about 20% and no more than about 80%), inclusive of all values and ranges therebetween. In some embodiments, the charging can be to about 10% SOC, about 15% SOC, about 20% SOC, about 25% SOC, about 30% SOC, about 35% SOC, about 40% SOC, about 45% SOC, about 50% SOC, about 55% SOC, about 60% SOC, about 65% SOC, about 70% SOC, about 75% SOC, about 80% SOC, about 85% SOC, about 90% SOC, about 95% SOC, or about 100% SOC.

In some embodiments, the charging can be at a rate of at least about 0.1 C, at least about 0.2 C, at least about 0.3 C, at least about 0.4 C, at least about 0.5 C, at least about 0.6 C, at least about 0.7 C, at least about 0.8 C, at least about 0.9 C, at least about 1 C, at least about 2 C, at least about 3 C, at least about 4 C, at least about 5 C, at least about 6 C, at least about 7 C, at least about 8 C, or at least about 9 C. In some embodiments, the charging can be at a rate of no more than about 10 C, no more than about 9 C, no more than about 8 C, no more than about 7 C, no more than about 6 C, no more than about 5 C, no more than about 4 C, no more than about 3 C, no more than about 2 C, no more than about 1 C, no more than about 0.9 C, no more than about 0.8 C, no more than about 0.7 C, no more than about 0.6 C, no more than about 0.5 C, no more than about 0.4 C, no more than about 0.3 C, or no more than about 0.2 C. Combinations of the above-referenced charging rates are also possible (e.g., at least about 0.1 C and no more than about 10 C, or at least about 0.5 C and no more than about 5 C), inclusive of all values and ranges therebetween. In some embodiments, the charging can be at a rate of about 0.1 C, about 0.2 C, about 0.3 C, about 0.4 C, about 0.5 C, about 0.6 C, about 0.7 C, about 0.8 C, about 0.9 C, about 1 C, about 2 C, about 3 C, about 4 C, about 5 C, about 6 C, about 7 C, about 8 C, about 9 C, or about 10 C.

In some embodiments, the calibrating electrical energy transfer can include discharging the electrochemical cell. In some embodiments, the discharging can be to at least about 10% SOC, at least about 15% SOC, at least about 20% SOC, at least about 25% SOC, at least about 30% SOC, at least about 35% SOC, at least about 40% SOC, at least about 45% SOC, at least about 50% SOC, at least about 55% SOC, at least about 60% SOC, at least about 65% SOC, at least about 70% SOC, at least about 75% SOC, at least about 80% SOC, at least about 85% SOC, at least about 90% SOC, or at least about 95% SOC. In some embodiments, the discharging can be to no more than about 100% SOC, no more than about 95% SOC, no more than about 90% SOC, no more than about 85% SOC, no more than about 80% SOC, no more than about 75% SOC, no more than about 70% SOC, no more than about 65% SOC, no more than about 60% SOC, no more than about 55% SOC, no more than about 50% SOC, no more than about 45% SOC, no more than about 40% SOC, no more than about 35% SOC, no more than about 30% SOC, no more than about 25% SOC, no more than about 20% SOC, or no more than about 15% SOC. Combinations of the above-referenced SOC values are also possible (e.g., at least about 10% and no more than about 100%, or at least about 20% and no more than about 80%), inclusive of all values and ranges therebetween. In some embodiments, the discharging can be to about 10% SOC, about 15% SOC, about 20% SOC, about 25% SOC, about 30% SOC, about 35% SOC, about 40% SOC, about 45% SOC, about 50% SOC, about 55% SOC, about 60% SOC, about 65% SOC, about 70% SOC, about 75% SOC, about 80% SOC, about 85% SOC, about 90% SOC, about 95% SOC, or about 100% SOC.

In some embodiments, the discharging can be at a rate of at least about 0.1 C, at least about 0.2 C, at least about 0.3 C, at least about 0.4 C, at least about 0.5 C, at least about 0.6 C, at least about 0.7 C, at least about 0.8 C, at least about 0.9 C, at least about 1 C, at least about 2 C, at least about 3 C, at least about 4 C, at least about 5 C, at least about 6 C, at least about 7 C, at least about 8 C, or at least about 9 C. In some embodiments, the discharging can be at a rate of no more than about 10 C, no more than about 9 C, no more than about 8 C, no more than about 7 C, no more than about 6 C, no more than about 5 C, no more than about 4 C, no more than about 3 C, no more than about 2 C, no more than about 1 C, no more than about 0.9 C, no more than about 0.8 C, no more than about 0.7 C, no more than about 0.6 C, no more than about 0.5 C, no more than about 0.4 C, no more than about 0.3 C, or no more than about 0.2 C. Combinations of the above-referenced charging rates are also possible (e.g., at least about 0.1 C and no more than about 10 C, or at least about 0.5 C and no more than about 5 C), inclusive of all values and ranges therebetween. In some embodiments, the discharging can be at a rate of about 0.1 C, about 0.2 C, about 0.3 C, about 0.4 C, about 0.5 C, about 0.6 C, about 0.7 C, about 0.8 C, about 0.9 C, about 1 C, about 2 C, about 3 C, about 4 C, about 5 C, about 6 C, about 7 C, about 8 C, about 9 C, or about 10 C.

Step 12 includes determining a plurality of calibration voltage differences between the first electrode and the interlayer to form a baseline parameter. In some embodiments, the parameter can include a voltage curve (e.g., a voltage vs. time curve or a voltage vs. SOC curve). These voltage measurements and/or recordings can be executed concurrently with the calibrating electrical energy transfer of step 11. In some embodiments, the first electrode can include the anode (i.e., the voltage recorded at step 12 can be between the anode and the interlayer). In some embodiments, the first electrode can include the cathode.

In some embodiments, step 12 can include executing and/or recording at least about 1, at least about 2, at least about 3, at least about 4, at least about 5, at least about 6, at least about 7, at least about 8, at least about 9, at least about 10, at least about 20, at least about 30, at least about 40, at least about 50, at least about 60, at least about 70, at least about 80, at least about 90, at least about 100, at least about 200, at least about 300, at least about 400, at least about 500, at least about 600, at least about 700, at least about 800, at least about 900, at least about 1,000, at least about 2,000, at least about 3,000, at least about 4,000, at least about 5,000, at least about 6,000, at least about 7,000, at least about 8,000, or at least about 9,000 voltage measurements between the first electrode and the interlayer. In some embodiments, step 12 can include executing and/or recording no more than about 10,000, no more than about 9,000, no more than about 8,000, no more than about 7,000, no more than about 6,000, no more than about 5,000, no more than about 4,000, no more than about 3,000, no more than about 2,000, no more than about 1,000, no more than about 900, no more than about 800, no more than about 700, no more than about 600, no more than about 500, no more than about 400, no more than about 300, no more than about 200, no more than about 100, no more than about 90, no more than about 80, no more than about 70, no more than about 60, no more than about 50, no more than about 40, no more than about 30, no more than about 20, no more than about 10, no more than about 9, no more than about 8, no more than about 7, no more than about 6, no more than about 5, no more than about 4, no more than about 3, or no more than about 2 voltage measurements between the first electrode and the interlayer. Combinations of the above-referenced numbers of measurements are also possible (e.g., at least about 1 and no more than about 10,000, or at least about 50 and no more than about 1,000), inclusive of all values and ranges therebetween. In some embodiments, step 12 can include executing and/or recording about 1, about 2, about 3, about 4, about 5, about 6, about 7, about 8, about 9, about 10, about 20, about 30, about 40, about 50, about 60, about 70, about 80, about 90, about 100, about 200, about 300, about 400, about 500, about 600, about 700, about 800, about 900, about 1,000, about 2,000, about 3,000, about 4,000, about 5,000, about 6,000, about 7,000, about 8,000, about 9,000, or about 10,000 voltage measurements between the first electrode and the interlayer.

In general, more data points of measurement between the first electrode and the interlayer can lead to more robust calibration curves and a more robust basis for comparison. In some embodiments, the measuring and/or recording of the voltage differences between the first electrode and the interlayer can include an automated or computer-executed process (e.g., executed by the controller 170). In some embodiments, the baseline parameter or calibration curve can be described by either of the following equations (Equation 1 for charge, Equation 2 for discharge):

$${v}_{t} = Δ V ( 1 - {e}^{t / τ} ) \qquad Equation 1$$

$${v}_{t} = {Δ Ve}^{t / τ} \qquad Equation 2$$

### Where:

vₜ is a time-dependent voltage difference between the first electrode and the interlayer;
ΔV is an applied voltage difference between the first electrode and the interlayer;
t is time; and
τ is a resistance-capacitance (RC) time constant.

These equations can create a predictable response curve for the evaluation of the health of connections between an external circuit and the electrochemical cell in real time. Additionally, standard curve fitting can be used to estimate both the equivalent circuit resistance and capacitance and the response of the interlayer to stimuli to the electrochemical cell, as described below in greater detail with respect to step 15 and step 16. In some embodiments, the data recorded for the parameter at step 12 can be modified in real time via artificial intelligence (AI) advanced filtering. In some embodiments, this filtering can include filtering slope data/calculations, curve data, RC time constant data/calculations, and/or offset voltage data/calculations. In some embodiments, the voltage applied between the first electrode and the second electrode can be via a constant voltage source. In some embodiments, the voltage applied between the first electrode and the second electrode can be via a variable voltage source.

Step 13 includes performing an operational electrical energy transfer between the first electrode and the second electrode. In some embodiments, the operational electrical energy transfer can include an electron transfer, an ion transfer, and/or any other suitable electrical energy transfer. In some embodiments, the operational electrical energy transfer can be the same or substantially similar to the calibrating electrical energy transfer of step 11. In some embodiments, the operational electrical energy transfer can include flowing the electrons in the same direction as the calibrating electrical energy transfer of step 11 (i.e., if the calibrating electrical energy transfer includes a charge, the operational electrical energy transfer can include a charge, or if the calibrating electrical energy transfer includes a discharge, the operational electrical energy transfer can include a discharge).

In some embodiments, the operational electrical energy transfer can occur after about 1 minute, about 5 minutes, about 10 minutes, about 30 minutes, about 1 hour, about 5 hours, about 10 hours, about 20 hours, about 1 day, about 5 days, about 10 days, about 30 days, about 60 days, about 90 days, about 180 days, or about 1 year of operation, inclusive of all values and ranges therebetween. In some embodiments, the operational electrical energy transfer can occur after about 1, about 2, about 3, about 4, about 5, about 6, about 7, about 8, about 9, about 10, about 20, about 30, about 40, about 50, about 60, about 70, about 80, about 90, about 100, about 200, about 300, about 400, about 500, about 600, about 700, about 800, about 900, about 1,000, about 2,000, about 3,000, about 4,000, about 5,000, about 6,000, about 7,000, about 8,000, about 9,000, or about 10,000 charge/discharge cycles, inclusive of all values and ranges therebetween.

In some embodiments, the operational electrical energy transfer can include charging the electrochemical cell. In some embodiments, the charging can be to at least about 10% SOC, at least about 15% SOC, at least about 20% SOC, at least about 25% SOC, at least about 30% SOC, at least about 35% SOC, at least about 40% SOC, at least about 45% SOC, at least about 50% SOC, at least about 55% SOC, at least about 60% SOC, at least about 65% SOC, at least about 70% SOC, at least about 75% SOC, at least about 80% SOC, at least about 85% SOC, at least about 90% SOC, or at least about 95% SOC. In some embodiments, the charging can be to no more than about 100% SOC, no more than about 95% SOC, no more than about 90% SOC, no more than about 85% SOC, no more than about 80% SOC, no more than about 75% SOC, no more than about 70% SOC, no more than about 65% SOC, no more than about 60% SOC, no more than about 55% SOC, no more than about 50% SOC, no more than about 45% SOC, no more than about 40% SOC, no more than about 35% SOC, no more than about 30% SOC, no more than about 25% SOC, no more than about 20% SOC, or no more than about 15% SOC. Combinations of the above-referenced SOC values are also possible (e.g., at least about 10% and no more than about 100%, or at least about 20% and no more than about 80%), inclusive of all values and ranges therebetween. In some embodiments, the charging can be to about 10% SOC, about 15% SOC, about 20% SOC, about 25% SOC, about 30% SOC, about 35% SOC, about 40% SOC, about 45% SOC, about 50% SOC, about 55% SOC, about 60% SOC, about 65% SOC, about 70% SOC, about 75% SOC, about 80% SOC, about 85% SOC, about 90% SOC, about 95% SOC, or about 100% SOC.

In some embodiments, the charging can be at a rate of at least about 0.1 C, at least about 0.2 C, at least about 0.3 C, at least about 0.4 C, at least about 0.5 C, at least about 0.6 C, at least about 0.7 C, at least about 0.8 C, at least about 0.9 C, at least about 1 C, at least about 2 C, at least about 3 C, at least about 4 C, at least about 5 C, at least about 6 C, at least about 7 C, at least about 8 C, or at least about 9 C. In some embodiments, the charging can be at a rate of no more than about 10 C, no more than about 9 C, no more than about 8 C, no more than about 7 C, no more than about 6 C, no more than about 5 C, no more than about 4 C, no more than about 3 C, no more than about 2 C, no more than about 1 C, no more than about 0.9 C, no more than about 0.8 C, no more than about 0.7 C, no more than about 0.6 C, no more than about 0.5 C, no more than about 0.4 C, no more than about 0.3 C, or no more than about 0.2 C. Combinations of the above-referenced charging rates are also possible (e.g., at least about 0.1 C and no more than about 10 C, or at least about 0.5 C and no more than about 5 C), inclusive of all values and ranges therebetween. In some embodiments, the charging can be at a rate of about 0.1 C, about 0.2 C, about 0.3 C, about 0.4 C, about 0.5 C, about 0.6 C, about 0.7 C, about 0.8 C, about 0.9 C, about 1 C, about 2 C, about 3 C, about 4 C, about 5 C, about 6 C, about 7 C, about 8 C, about 9 C, or about 10 C.

In some embodiments, the operational electrical energy transfer can include discharging the electrochemical cell. In some embodiments, the discharging can be to at least about 10% SOC, at least about 15% SOC, at least about 20% SOC, at least about 25% SOC, at least about 30% SOC, at least about 35% SOC, at least about 40% SOC, at least about 45% SOC, at least about 50% SOC, at least about 55% SOC, at least about 60% SOC, at least about 65% SOC, at least about 70% SOC, at least about 75% SOC, at least about 80% SOC, at least about 85% SOC, at least about 90% SOC, or at least about 95% SOC. In some embodiments, the discharging can be to no more than about 100% SOC, no more than about 95% SOC, no more than about 90% SOC, no more than about 85% SOC, no more than about 80% SOC, no more than about 75% SOC, no more than about 70% SOC, no more than about 65% SOC, no more than about 60% SOC, no more than about 55% SOC, no more than about 50% SOC, no more than about 45% SOC, no more than about 40% SOC, no more than about 35% SOC, no more than about 30% SOC, no more than about 25% SOC, no more than about 20% SOC, or no more than about 15% SOC. Combinations of the above-referenced SOC values are also possible (e.g., at least about 10% and no more than about 100%, or at least about 20% and no more than about 80%), inclusive of all values and ranges therebetween. In some embodiments, the discharging can be to about 10% SOC, about 15% SOC, about 20% SOC, about 25% SOC, about 30% SOC, about 35% SOC, about 40% SOC, about 45% SOC, about 50% SOC, about 55% SOC, about 60% SOC, about 65% SOC, about 70% SOC, about 75% SOC, about 80% SOC, about 85% SOC, about 90% SOC, about 95% SOC, or about 100% SOC.

In some embodiments, the discharging can be at a rate of at least about 0.1 C, at least about 0.2 C, at least about 0.3 C, at least about 0.4 C, at least about 0.5 C, at least about 0.6 C, at least about 0.7 C, at least about 0.8 C, at least about 0.9 C, at least about 1 C, at least about 2 C, at least about 3 C, at least about 4 C, at least about 5 C, at least about 6 C, at least about 7 C, at least about 8 C, or at least about 9 C. In some embodiments, the discharging can be at a rate of no more than about 10 C, no more than about 9 C, no more than about 8 C, no more than about 7 C, no more than about 6 C, no more than about 5 C, no more than about 4 C, no more than about 3 C, no more than about 2 C, no more than about 1 C, no more than about 0.9 C, no more than about 0.8 C, no more than about 0.7 C, no more than about 0.6 C, no more than about 0.5 C, no more than about 0.4 C, no more than about 0.3 C, or no more than about 0.2 C. Combinations of the above-referenced charging rates are also possible (e.g., at least about 0.1 C and no more than about 10 C, or at least about 0.5 C and no more than about 5 C), inclusive of all values and ranges therebetween. In some embodiments, the discharging can be at a rate of about 0.1 C, about 0.2 C, about 0.3 C, about 0.4 C, about 0.5 C, about 0.6 C, about 0.7 C, about 0.8 C, about 0.9 C, about 1 C, about 2 C, about 3 C, about 4 C, about 5 C, about 6 C, about 7 C, about 8 C, about 9 C, or about 10 C.

Step 14 includes determining a plurality of operational voltage differences between the first electrode and the interlayer to form an operational parameter. In some embodiments, the operational parameter can include a voltage curve (e.g., a voltage vs. time curve or a voltage vs. SOC curve). These voltage measurements and/or recordings can be executed concurrently with the operational electrical energy transfer of step 13. In some embodiments, the first electrode can include the anode (i.e., the voltage recorded at step 14 can be between the anode and the interlayer). In some embodiments, the first electrode can include the cathode. The parameter developed, determined, or inferred at step 14 is compared to the parameter developed, determined, or inferred at step 12, as described below in greater detail with respect to step 17.

In some embodiments, step 14 can include executing and/or recording at least about 1, at least about 2, at least about 3, at least about 4, at least about 5, at least about 6, at least about 7, at least about 8, at least about 9, at least about 10, at least about 20, at least about 30, at least about 40, at least about 50, at least about 60, at least about 70, at least about 80, at least about 90, at least about 100, at least about 200, at least about 300, at least about 400, at least about 500, at least about 600, at least about 700, at least about 800, at least about 900, at least about 1,000, at least about 2,000, at least about 3,000, at least about 4,000, at least about 5,000, at least about 6,000, at least about 7,000, at least about 8,000, or at least about 9,000 voltage measurements between the first electrode and the interlayer. In some embodiments, step 14 can include executing and/or recording no more than about 10,000, no more than about 9,000, no more than about 8,000, no more than about 7,000, no more than about 6,000, no more than about 5,000, no more than about 4,000, no more than about 3,000, no more than about 2,000, no more than about 1,000, no more than about 900, no more than about 800, no more than about 700, no more than about 600, no more than about 500, no more than about 400, no more than about 300, no more than about 200, no more than about 100, no more than about 90, no more than about 80, no more than about 70, no more than about 60, no more than about 50, no more than about 40, no more than about 30, no more than about 20, no more than about 10, no more than about 9, no more than about 8, no more than about 7, no more than about 6, no more than about 5, no more than about 4, no more than about 3, or no more than about 2 voltage measurements between the first electrode and the interlayer. Combinations of the above-referenced numbers of measurements are also possible (e.g., at least about 1 and no more than about 10,000, or at least about 50 and no more than about 1,000), inclusive of all values and ranges therebetween. In some embodiments, step 14 can include executing and/or recording about 1, about 2, about 3, about 4, about 5, about 6, about 7, about 8, about 9, about 10, about 20, about 30, about 40, about 50, about 60, about 70, about 80, about 90, about 100, about 200, about 300, about 400, about 500, about 600, about 700, about 800, about 900, about 1,000, about 2,000, about 3,000, about 4,000, about 5,000, about 6,000, about 7,000, about 8,000, about 9,000, or about 10,000 voltage measurements between the first electrode and the interlayer.

In some embodiments, the measuring and/or recording of the voltage differences between the first electrode and the interlayer can include an automated or computer-executed process. In some embodiments, the baseline parameter or calibration curve can be described by either of Equation 1 or Equation 2, as described above.

As described above with reference to step 12, these equations can create a predictable response curve for the evaluation of the health of connections between an external circuit and the electrochemical cell in real time. In some embodiments, the data recorded for the parameter at step 14 can be modified in real time via AI advanced filtering. In some embodiments, this filtering can include filtering slope data/calculations, curve data, RC time constant data/calculations, and/or offset voltage data/calculations. Differences between the baseline parameter and the operational parameter can be characterized by a difference between the RC time constant of the baseline parameter and the RC time constant of the operational parameter. In some embodiments, the voltage applied between the first electrode and the second electrode can be via a constant voltage source. In some embodiments, the voltage applied between the first electrode and the second electrode can be via a variable voltage source.

Step 15 is optional and includes performing a stimulation of the electrochemical cell. In some embodiments, step 15 can include a stimulation of the interlayer (e.g., a voltage stimulation). The stimulation 15 can aid in acquiring additional baseline and/or comparison data for detection of a problem in the electrochemical cell.

In some embodiments, the stimulation at step 15 can include performing a pullup of the interlayer. In some embodiments, the stimulation at step 15 can include performing a pulldown of the interlayer. In some embodiments, the pullup and/or pulldown resistance can be at least about 0.1 kΩ, at least about 0.2 kΩ, at least about 0.3 kΩ, at least about 0.4 kΩ, at least about 0.5 kΩ, at least about 0.6 kΩ, at least about 0.7 kΩ, at least about 0.8 kΩ, at least about 0.9 kΩ, at least about 1 kΩ, at least about 2 kΩ, at least about 3 kΩ, at least about 4 kΩ, at least about 5 kΩ, at least about 6 kΩ, at least about 7 kΩ, at least about 8 kΩ, or at least about 9 kΩ. In some embodiments, the pullup and/or pulldown resistance can be no more than about 10 kΩ, no more than about 9 kΩ, no more than about 8 kΩ, no more than about 7 kΩ, no more than about 6 kΩ, no more than about 5 kΩ, no more than about 4 kΩ, no more than about 3 kΩ, no more than about 2 kΩ, no more than about 1 kΩ, no more than about 0.9 kΩ, no more than about 0.8 kΩ, no more than about 0.7 kΩ, no more than about 0.6 kΩ, no more than about 0.5 kΩ, no more than about 0.4 kΩ, no more than about 0.3 kΩ, or no more than about 0.2 kΩ. Combinations of the above-referenced pullup/pulldown resistances are also possible (e.g., at least about 0.1 kΩ and no more than about 10 kΩ, or at least about 0.3 kΩ and no more than about 7 kΩ, inclusive of all values and ranges therebetween. In some embodiments, the pullup and/or pulldown resistance can be about 0.1 kΩ, about 0.2 kΩ, about 0.3 kΩ, about 0.4 kΩ, about 0.5 kΩ, about 0.6 kΩ, about 0.7 kΩ, about 0.8 kΩ, about 0.9 kΩ, about 1 kΩ, about 2 kΩ, about 3 kΩ, about 4 kΩ, about 5 kΩ, about 6 kΩ, about 7 kΩ, about 8 kΩ, about 9 kΩ, or about 10 kΩ.

In the case of a pullup (e.g., pulling a voltage or potential of the interlayer towards the cathode) with a fixed, known resistance that is much smaller than the equivalent circuit impedance, a resulting discharge curve (e.g., as developed in step 16, described below) of the capacitors in a circuit connected to the electrochemical cell can be measured. The capacitance value can be calculated via Equation 1 or Equation 2, as described above. When the fixed resistance is removed (i.e., the pullup is removed), the voltage of the interlayer can return to a nominal value based on the internal resistance of an equivalent circuit. Similar analyses can be performed in the case of a pulldown (i.e., pulling the interlayer to the anode).

Step 16 is optional and includes forming additional baseline and operational parameters of the electrochemical cell. When applying the stimulus of step 15, an additional calibration parameter can be developed (i.e., the same or substantially similar to step 12), such that data is developed for how the electrochemical cell reacts to stimuli before any dendrites or other electrode issues have formed. In some embodiments, multiple stimuli can be performed to create a parametric table of the expected response of the electrochemical cell to known stimuli. For example, a parametric table can include a list of different pullup and pulldown resistances and the expected response in the voltage curve of the electrochemical cell during calibration. Later (e.g., during steps 13 and/or 14), the same or substantially similar pullups and pulldowns can be performed to investigate how the cell voltage responds to such stimuli after many cycles of operation. In some embodiments, steps 15 and 16 can occur at least partially before cycling the electrochemical cell and performing the operational electrical energy transfer of step 13. More specifically, multiple calibration parameters can be developed before cycling or operating the electrochemical cell, and those calibration parameters can be compared to operational parameters developed after some cycling and under comparable stimuli. In general, more calibration parameters will provide more bases for comparison, such that the cell has a more robust response system.

Step 17 includes diagnosing the electrochemical cell based on the baseline parameter and the operational parameter. In some embodiments, step 17 can include comparisons between multiple baseline parameters and multiple operational parameters (i.e., when step 15 and step 16 have been executed, developing multiple calibration parameters). In some embodiments, diagnostic methods can include evaluating the differences between the baseline parameter and the operational parameter. In the case in which one or more stimuli have been applied to the electrochemical cell, diagnostic methods can evaluate the difference of the measured response to the baseline parameters with the same stimuli. In either case, detected variations between the two parameters can indicate connection health issues in the electrochemical cell and/or dendrite formation issues.

In the case of dendrite formation issues, the resistance of the dendrite changes the RC time constant of the circuit. In such a case, even if there has not been a short circuit between the first electrode and the interlayer (i.e., the voltage between the first electrode and the interlayer has not yet decreased to below a threshold value), a change in the equivalent resistance of the system can indicate the presence of dendrites in the first electrode. In other words, such diagnostic methods can detect the presence of dendrites before the dendrites have penetrated either of the separators.

In some embodiments, comparisons between the baseline parameters and the operational parameters can include comparing the time-averaged voltage of the baseline parameters and the operational parameters when the electrochemical cell is subject to the same or substantially similar charge/discharge. In some embodiments, comparisons between the baseline parameters and the operational parameters can include calculating a total area between the voltage vs. time curves during calibration and operation. In some embodiments, comparisons between the baseline parameters and the operational parameters can include measuring the differences between the rates of change of voltage with respect to time between the two parameters (i.e., differences between dV/dt at a given time, or a given SOC). In some embodiments, comparisons between the baseline parameters and the operational parameters can include comparing the RC time constant of the baseline parameters and the operational parameters. In some embodiments, comparisons between the baseline parameters and the operational parameters can include digital filtering including, but not limited to Infinite Impulse Response (IIR) filtering, Finite Impulse Response (FIR) filtering, S domain filtering, Fast Fourier Transform (FFT) filtering, AFFT filtering, any other suitable filtering or model based system analysis, or any suitable combination thereof.

In some embodiments, the electrochemical cell can be designated as healthy at step 17 if a parameter difference between the baseline parameter and the operational parameter is less than a designated threshold value. In some embodiments, the electrochemical cell can be designated as having connectivity and/or dendrite issues if the parameter difference between the baseline parameter and the operational parameter is greater than the threshold value.

In some embodiments, the threshold value for the difference between the time-averaged voltage between the baseline parameter and the operational parameter can be at least about 0.01 V, at least about 0.02 V, at least about 0.03 V, at least about 0.04 V, at least about 0.05 V, at least about 0.06 V, at least about 0.07 V, at least about 0.08 V, at least about 0.09 V, at least about 0.1 V, at least about 0.2 V, at least about 0.3 V, at least about 0.4 V, at least about 0.5 V, at least about 0.6 V, at least about 0.7 V, at least about 0.8 V, at least about 0.9 V, at least about 1 V, at least about 1.1 V at least about 1.2 V, at least about 1.3 V, at least about 1.4 V, at least about 1.5 V, at least about 1.6 V, at least about 1.7 V, at least about 1.8 V, or at least about 1.9 V. In some embodiments, the threshold value for the difference between the time-averaged voltage between the baseline parameter and the operational parameter can be no more than about 2 V, no more than about 1.9 V, no more than about 1.8 V, no more than about 1.7 V, no more than about 1.6 V, no more than about 1.5 V, no more than about 1.4 V, no more than about 1.3 V, no more than about 1.2 V, no more than about 1.1 V, no more than about 1 V, no more than about 0.9 V, no more than about 0.8 V, no more than about 0.7 V, no more than about 0.6 V, no more than about 0.5 V, no more than about 0.4 V, no more than about 0.3 V, no more than about 0.2 V, no more than about 0.1 V, no more than about 0.09 V, no more than about 0.08 V, no more than about 0.07 V, no more than about 0.06 V, no more than about 0.05 V, no more than about 0.04 V, no more than about 0.03 V, or no more than about 0.02 V. Combinations of the above-referenced voltage differences are also possible (e.g., at least about 0.01 V and no more than about 2 V, or at least about 0.1 V and no more than about 1 V), inclusive of all values and ranges therebetween. In some embodiments, the threshold value for the difference between the time-averaged voltage between the baseline parameter and the operational parameter can be about 0.01 V, about 0.02 V, about 0.03 V, about 0.04 V, about 0.05 V, about 0.06 V, about 0.07 V, about 0.08 V, about 0.09 V, about 0.1 V, about 0.2 V, about 0.3 V, about 0.4 V, about 0.5 V, about 0.6 V, about 0.7 V, about 0.8 V, about 0.9 V, about 1 V, about 1.1 V about 1.2 V, about 1.3 V, about 1.4 V, about 1.5 V, about 1.6 V, about 1.7 V, about 1.8 V, about 1.9 V, or about 2 V.

In some embodiments, the threshold value for the total area between the baseline parameter and the operational parameter can be at least about 0.1 V·s, at least about 0.2 V·s, at least about 0.3 V·s, at least about 0.4 V·s, at least about 0.5 V·s, at least about 0.6 V·s, at least about 0.7 V·s, at least about 0.8 V·s, at least about 0.9 V·s, at least about 1 V·s, at least about 2 V·s, at least about 3 V·s, at least about 4 V·s, at least about 5 V·s, at least about 6 V·s, at least about 7 V·s, at least about 8 V·s, at least about 9 V·s, at least about 10 V·s, at least about 20 V·s, at least about 30 V·s, at least about 40 V·s, at least about 50 V·s, at least about 60 V·s, at least about 70 V·s, at least about 80 V·s, at least about 90 V·s, at least about 100 V·s, at least about 200 V·s, at least about 300 V·s, at least about 400 V·s, at least about 500 V·s, at least about 600 V·s, at least about 700 V·s, at least about 800 V·s, or at least about 900 V·s. In some embodiments, the threshold value for the total area between the baseline parameter and the operational parameter can be no more than about 1,000 V·s, no more than about 900 V·s, no more than about 800 V·s, no more than about 700 V·s, no more than about 600 V·s, no more than about 500 V·s, no more than about 400 V·s, no more than about 300 V·s, no more than about 200 V·s, no more than about 100 V·s, no more than about 90 V·s, no more than about 80 V·s, no more than about 70 Vs, no more than about 60 V·s, no more than about 50 V·s, no more than about 40 V·s, no more than about 30 V·s, no more than about 20 V·s, no more than about 10 V·s, no more than about 9 V·s, no more than about 8 V·s, no more than about 7 V·s, no more than about 6 V·s, no more than about 5 V·s, no more than about 4 V·s, no more than about 3 V·s, no more than about 2 V·s, no more than about 1 V·s, no more than about 0.9 V·s, no more than about 0.8 V·s, no more than about 0.7 V·s, no more than about 0.6 V·s, no more than about 0.5 V·s, no more than about 0.4 V·s, no more than about 0.3 Vs, or no more than about 0.2 V·s. Combinations of the above-referenced area differences are also possible (e.g., at least about 0.1 V·s and no more than about 1,000 V·s, or at least about 50 V's and no more than about 500 V·s), inclusive of all values and ranges therebetween. In some embodiments, the threshold value for the total area between the baseline parameter and the operational parameter can be about 0.1 V·s, about 0.2 V·s, about 0.3 V·s, about 0.4 V·s, about 0.5 V·s, about 0.6 V·s, about 0.7 V·s, about 0.8 V·s, about 0.9 V·s, about 1 V·s, about 2 V·s, about 3 V·s, about 4 V·s, about 5 V·s, about 6 V·s, about 7 V·s, about 8 V·s, about 9 V·s, about 10 V·s, about 20 V·s, about 30 V·s, about 40 V·s, about 50 V·s, about 60 V·s, about 70 V·s, about 80 V·s, about 90 V·s, about 100 V·s, about 200 V·s, about 300 V·s, about 400 V·s, about 500 V·s, about 600 V·s, about 700 V·s, about 800 V·s, about 900 V·s, or about 1,000 V·s.

In some embodiments, the threshold value for dV/dt difference between the baseline parameter and the operational parameter can be at least about 0.001 V/s, at least about 0.002 V/s, at least about 0.003 V/s, at least about 0.004 V/s, at least about 0.005 V/s, at least about 0.006 V/s, at least about 0.007 V/s, at least about 0.008 V/s, at least about 0.009 V/s, at least about 0.01 V/s, at least about 0.02 V/s, at least about 0.03 V/s, at least about 0.04 V/s, at least about 0.05 V/s, at least about 0.06 V/s, at least about 0.07 V/s, at least about 0.08 V/s, at least about 0.09 V/s, at least about 0.1 V/s, at least about 0.2 V/s, at least about 0.3 V/s, at least about 0.4 V/s, at least about 0.5 V/s, at least about 0.6 V/s, at least about 0.7 V/s, at least about 0.8 V/s, or at least about 0.9 V/s. In some embodiments, the threshold value for dV/dt difference between the baseline parameter and the operational parameter can be no more than about 1 V/s, no more than about 0.9 V/s, no more than about 0.8 V/s, no more than about 0.7 V/s, no more than about 0.6 V/s, no more than about 0.5 V/s, no more than about 0.4 V/s, no more than about 0.3 V/s, no more than about 0.2 V/s, no more than about 0.1 V/s, no more than about 0.09 V/s, no more than about 0.08 V/s, no more than about 0.07 V/s, no more than about 0.06 V/s, no more than about 0.05 V/s, no more than about 0.04 V/s, no more than about 0.03 V/s, no more than about 0.02 V/s, no more than about 0.01 V/s, no more than about 0.009 V/s, no more than about 0.008 V/s, no more than about 0.007 V/s, no more than about 0.006 V/s, no more than about 0.005 V/s, no more than about 0.004 V/s, no more than about 0.003 V/s, or no more than about 0.002 V/s. Combinations of the above-referenced dV/dt differences are also possible (e.g., at least about 0.001 V/s and no more than about 1 V/s, or at least about 0.01 V/s and no more than about 0.1 V/s), inclusive of all values and ranges therebetween. In some embodiments, the threshold value for dV/dt difference between the baseline parameter and the operational parameter can be about 0.001 V/s, about 0.002 V/s, about 0.003 V/s, about 0.004 V/s, about 0.005 V/s, about 0.006 V/s, about 0.007 V/s, about 0.008 V/s, about 0.009 V/s, about 0.01 V/s, about 0.02 V/s, about 0.03 V/s, about 0.04 V/s, about 0.05 V/s, about 0.06 V/s, about 0.07 V/s, about 0.08 V/s, about 0.09 V/s, about 0.1 V/s, about 0.2 V/s, about 0.3 V/s, about 0.4 V/s, about 0.5 V/s, about 0.6 V/s, about 0.7 V/s, about 0.8 V/s, about 0.9 V/s, or about 1 V/s.

In some embodiments, the threshold value for RC time constant difference between the baseline parameter and the operational parameter can be at least about 0.001 s, at least about 0.005 s, at least about 0.01 s, at least about 0.05 s, at least about 0.1 s, at least about 0.5 s, at least about 1 s, at least about 5 s, at least about 10 s, at least about 50 s, at least about 100 s, or at least about 500 s. In some embodiments, the threshold value for RC time constant difference between the baseline parameter and the operational parameter can be no more than about 1,000 s, no more than about 500 s, no more than about 100 s, no more than about 50 s, no more than about 10 s, no more than about 5 s, no more than about 1 s, no more than about 0.5 s, no more than about 0.1 s, no more than about 0.05 s, no more than about 0.01 s, or no more than about 0.005 s. Combinations of the above-referenced RC time constant values are also possible (e.g., at least about 0.001 s and no more than about 1,000 s, or at least about 0.1 s and no more than about 1 s), inclusive of all values and ranges therebetween. In some embodiments, the threshold value for RC time constant difference between the baseline parameter and the operational parameter can be about 0.001 s, about 0.005 s, about 0.01 s, about 0.05 s, about 0.1 s, about 0.5 s, about 1 s, about 5 s, about 10 s, about 50 s, about 100 s, about 500 s, or about 1,000 s.

In some embodiments, the diagnosis at step 17 can include diagnosing the circuit connected to the electrochemical cell as being open (i.e., indicating a connectivity issue). In such a case, a voltage change between the first electrode and the interlayer can be effectively instantaneous, independent of the relative impedance used for actuation. In cases with an open connection, the voltage difference between the first electrode and the interlayer can become zero or near-zero. There would be no characteristic charge curve as determined by the baseline charge curve and the circuit would be diagnosed as open. In the event of a short circuit between the interlayer and the cathode, the voltage of the interlayer would not change relative to the stimulus applied in step 15 and would instead be consistent with the voltage of the cathode. In the event of a short circuit between the interlayer and the anode, the voltage threshold of a full dendrite formation and connection to the interlayer can be assumed and faults would be activated. Additionally, the interlayer voltage would not change as a result of a stimulus or pulldown.

In some embodiments, the method 10 can include monitoring multiple electrochemical cells at once to detect a connection and/or dendrite issue in any of the cells, followed by individual monitoring of the electrochemical cells if an issue is detected. This can include electrically coupling each interlayer from each electrochemical cell and electrically coupling the anodes and/or the cathodes from each electrochemical cell, and measuring the voltage between a common (or same) connection interlayer connection point or individual interlayer connection points, and a common anode/cathode connection point. In some embodiments, the electrochemical cells can be connected in series. In some embodiments, the electrochemical cells can be connected in parallel. In some embodiments, the method 10 can include isolating the electrochemical cells from each other upon detecting an issue with the group of electrochemical cells. In some embodiments, the method can include discarding each unhealthy electrochemical cell and recycling each healthy electrochemical cell.

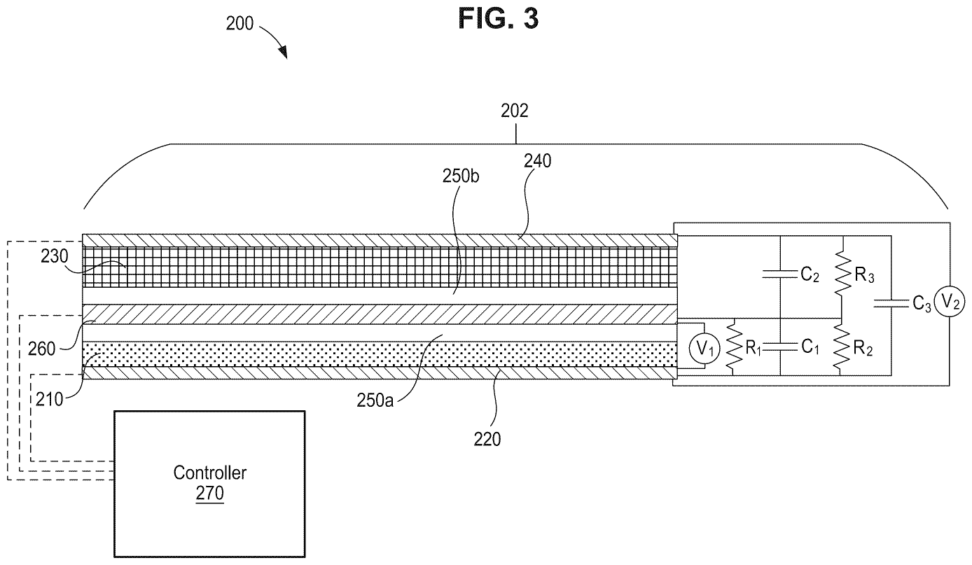

FIG. 3 is an illustration of an electrochemical cell system 200, according to an embodiment. As shown, the electrochemical cell system 200 includes an electrochemical cell 202 and a controller 270. As shown, the electrochemical cell 202 includes an anode 210 disposed on an anode current collector 220, a cathode 230 disposed on a cathode current collector 240, a first separator 250a disposed on the anode 210, a second separator 250b disposed on the cathode 230, and an interlayer 260 disposed between the first separator 250a and the second separator 250b. In some embodiments, the anode 210, the anode current collector 220, the cathode 230, the cathode current collector 240, the first separator 250a, the second separator 250b, the interlayer 260, and the controller 270 can be the same or substantially similar to the anode 110, the anode current collector 120, the cathode 130, the cathode current collector 140, the first separator 150a, the second separator 150b, the interlayer 160, and the controller 170, as described above with reference to FIGS. 1A-1B. Thus, certain aspects of the anode 210, the anode current collector 220, the cathode 230, the cathode current collector 240, the first separator 250a, the second separator 250b, the interlayer 260, and the controller 270 are not described in greater detail herein.

As shown, an equivalent circuit is shown connected to the electrochemical cell 202. This representation of the equivalent circuit is a simplified representation of the actual values and behaviors of the interlayer 260. Other representations (e.g., circuits, equations, curves) can also be valid for estimations and predictions of the behavior of the interlayer 260 to stimuli. The equivalent circuit includes a voltage monitor V₁ measuring voltage between the anode current collector 220 and the interlayer 260, a voltage monitor V₂ measuring voltage between the anode current collector 220 and the cathode current collector 240, resistors R₁, R₂ and capacitor C₁ between the anode current collector 220 and the interlayer 260, resistor R₃ and capacitor C₂ between the interlayer 260 and the cathode current collector 240, and capacitor C₃ between the anode current collector 220 and the cathode current collector 240.

FIG. 3 shows a basic level of electrical equivalent interactions between the interlayer 260 and other components of the electrochemical cell 202. As can be seen, there is a capacitive relationship between the anode 210 and the interlayer 260 and a capacitive relationship between the cathode 230 and the interlayer 260. Additionally, there is a resistive element that forms and transfers through the active material (i.e., in the anode 210 and the cathode 230). These electrical representations can be used to evaluate the effective performance of the interlayer 260 and to perform diagnostic methods (i.e., the method 10). Such diagnostics can include a short circuit between the interlayer 260 and the anode 210, a short circuit between the interlayer 260 and the cathode 230, dendrite formation, and an open connection on the circuit connecting to the electrochemical cell 202.

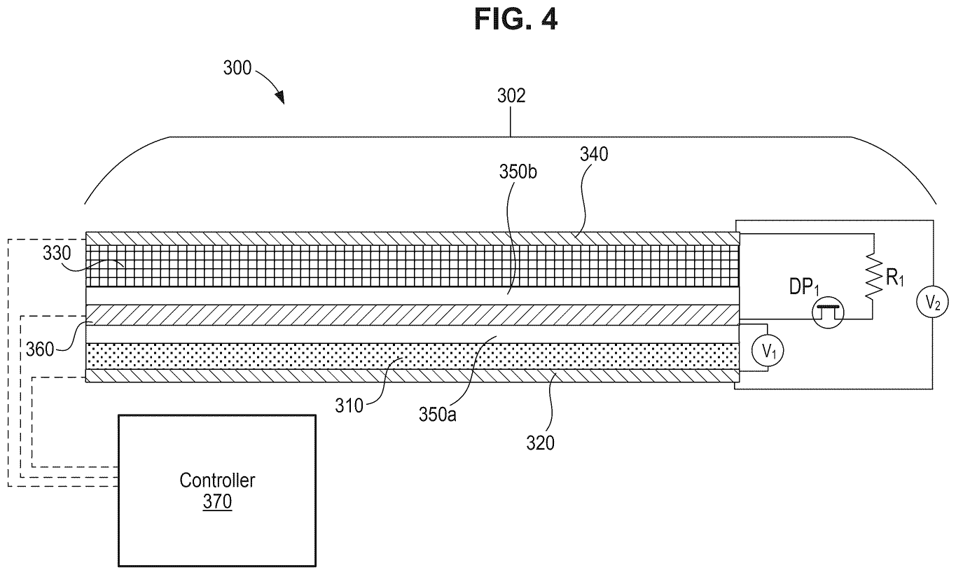

FIG. 4 is an illustration of an electrochemical cell system 300, according to an embodiment. As shown, the electrochemical cell system 300 includes an electrochemical cell 302 and a controller 370. As shown, the electrochemical cell 302 includes an anode 310 disposed on an anode current collector 320, a cathode 330 disposed on a cathode current collector 340, a first separator 350a disposed on the anode 310, a second separator 350b disposed on the cathode 330, and an interlayer 360 disposed between the first separator 350a and the second separator 350b. In some embodiments, the anode 310, the anode current collector 320, the cathode 330, the cathode current collector 340, the first separator 350a, the second separator 350b, the interlayer 360, and the controller 370 can be the same or substantially similar to the anode 110, the anode current collector 120, the cathode 130, the cathode current collector 140, the first separator 150a, the second separator 150b, the interlayer 160, and the controller 170, as described above with reference to FIGS. 1A-1B. Thus, certain aspects of the anode 310, the anode current collector 320, the cathode 330, the cathode current collector 340, the first separator 350a, the second separator 350b, the interlayer 360, and the controller 370 are not described in greater detail herein.

The circuit depicted in FIG. 4 shows a potential operation of the interlayer 360. As shown, a voltage monitor V₁ is positioned between the interlayer 360 and the anode current collector 320 and a voltage monitor V₂ is positioned between the anode current collector 320 and the cathode current collector 340. A pullup DPI and a resistor having a fixed, known resistance R₁ (also referred to as “resistor R₁”) are positioned between the interlayer 360 and the cathode current collector 340. In some embodiments, the circuit can include a pulldown (not shown) between the interlayer 360 and the anode current collector 320. In some embodiments, the circuit can include both a pullup and a pulldown in order to actuate the electrochemical cell system 300 to both the anode 310 and the cathode 330 alternately. The circuit shown in FIG. 4 can also be used as a test circuit to evaluate the relative values of the components of the circuit. By pulling a voltage or potential of the interlayer 360 to the cathode 330 (as shown in FIG. 4) with a fixed, known resistor R₁ that is much smaller than the equivalent circuit impedance, the resultant discharge curve of capacitors or equivalent capacitors (not shown) on the circuit can be measured and the capacitance value can be calculated via Equation 1 or Equation 2. When the fixed resistance (R₁) is removed, the voltage or potential of the interlayer 360 can return to a nominal value based on the internal resistance of the equivalent circuit. A parametric table of expected response curves to known stimuli can then be created (e.g., see step 15 and step 16, as described herein with reference to FIG. 2).

For diagnostic methods, an operational voltage curve can be measured against a calibration curve to detect variations, for example, due to connection health issues and/or dendrites forming in the electrochemical cell system 300. In the case of dendrite formation, the resistance of the dendrite can change the RC time constant of the circuit, even if the dendrite has not grown enough to penetrate either of the separators 350a, 350b to create a short circuit. A change in the equivalent resistance of the system may still be detectable. The electrochemical cell system 300 may also be able to perform a calibration or characterization of the voltage curve based on the fixed resistance. For accuracy, multiple values of resistance can be used to determine an average resultant circuit. A baseline curve model can also be formed for dV/dt correlation to a measured calibration value in the electrochemical cell system 300.

In the event of an open circuit sense connection, the voltage change can be effectively instantaneous, independent of the relative impedance used for actuation. In cases with an open connection, the voltage of the interlayer 360 can very quickly change to the same or approximately the same value of the excitation electrode (i.e., the electrode being pulled to). There can be comparatively no charge curve and the circuit can be immediately identifiable as open. In the event of a short circuit between the interlayer 360 and the cathode 330, the voltage of the interlayer 360 may not change significantly from the pullup and can represent the voltage of the cathode 330. In the event of a short circuit between the interlayer 360 and the anode 310, the voltage of the interlayer 360 may not change significantly from the pulldown and can represent the voltage of the anode 310.

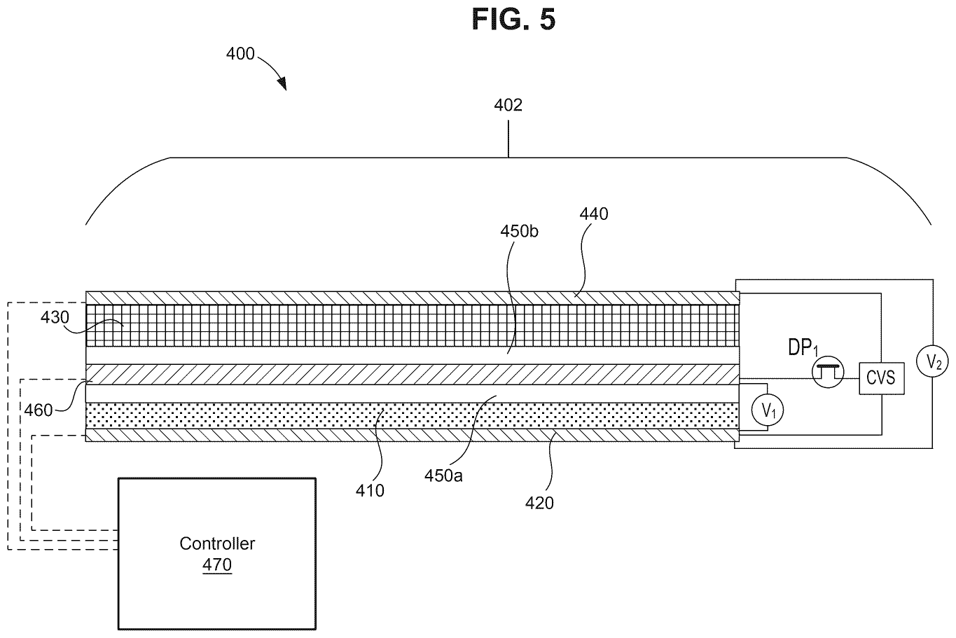

FIG. 5 is an illustration of an electrochemical cell system 400, according to an embodiment. As shown, the electrochemical cell system 400 includes an electrochemical cell 402 and a controller 470. As shown, the electrochemical cell 402 includes an anode 410 disposed on an anode current collector 420, a cathode 430 disposed on a cathode current collector 440, a first separator 450a disposed on the anode 410, a second separator 450b disposed on the cathode 430, and an interlayer 460 disposed between the first separator 450a and the second separator 450b. In some embodiments, the anode 410, the anode current collector 420, the cathode 430, the cathode current collector 440, the first separator 450a, the second separator 450b, the interlayer 460, and the controller 470 can be the same or substantially similar to the anode 110, the anode current collector 120, the cathode 130, the cathode current collector 140, the first separator 150a, the second separator 150b, the interlayer 160, and the controller 170, as described above with reference to FIGS. 1A-1B. Thus, certain aspects of the anode 410, the anode current collector 420, the cathode 430, the cathode current collector 440, the first separator 450a, the second separator 450b, the interlayer 460, and the controller 470 are not described in greater detail herein.

As shown, a voltage monitor V₁ is positioned between the anode current collector 420 and the interlayer 460. A voltage monitor V₂ is positioned between the cathode current collector 440 and the interlayer 460. A pullup/pulldown DPI is connected to the interlayer and a constant voltage source CVS acts as a three-terminal device, connecting the anode current collector 420, the cathode current collector 440, and the interlayer 460. While the constant voltage source CVS is shown as a three-terminal device, many different types of circuits can be used to create the voltage source. The constant voltage source CVS can provide relative potential to the interlayer 460. In testing, some electrochemical systems show greater benefit from connection to a constant voltage potential instead of relying on the relative voltage of the cathode 430 via a passive device. In some embodiments, the method 10 described above with reference to FIG. 2 can be applied to the electrochemical cell system 400.

By controlling the output impedance of the constant voltage source CVS, a fixed resistance and known voltage level can be used to charge the interlayer 460 to a specific value. The profile of the resultant charge curve can be described with the capacitive charge equations (e.g., Equation 2 or any methods described herein). It can then be possible to disconnect the constant voltage source CVS and allow the voltage of the interlayer 460 to recover. In this way, the equivalent circuit components can be calculated, as described herein. In some embodiments, diagnostic criteria can be employed using a function, curve fit, and/or any other suitable parameter.

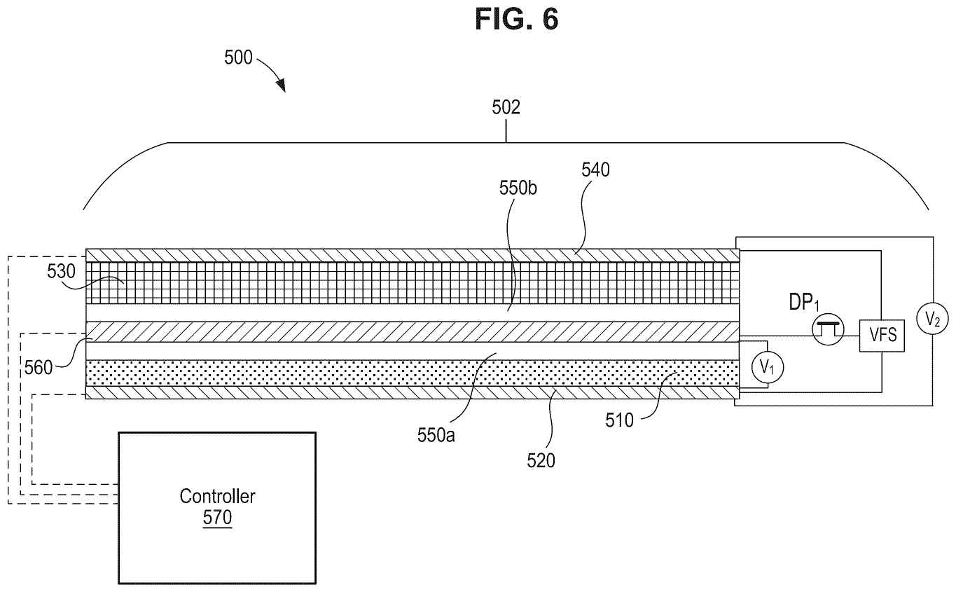

FIG. 6 is an illustration of an electrochemical cell system 500, according to an embodiment. As shown, the electrochemical cell system 500 includes an electrochemical cell 502 and a controller 570. As shown, the electrochemical cell 502 includes an anode 510 disposed on an anode current collector 520, a cathode 530 disposed on a cathode current collector 540, a first separator 550a disposed on the anode 510, a second separator 550b disposed on the cathode 530, and an interlayer 560 disposed between the first separator 550a and the second separator 550b. In some embodiments, the anode 510, the anode current collector 520, the cathode 530, the cathode current collector 540, the first separator 550a, the second separator 550b, the interlayer 560, and the controller 570 can be the same or substantially similar to the anode 110, the anode current collector 120, the cathode 130, the cathode current collector 140, the first separator 150a, the second separator 150b, the interlayer 160, and the controller 170, as described above with reference to FIGS. 1A-1B. Thus, certain aspects of the anode 510, the anode current collector 520, the cathode 530, the cathode current collector 540, the first separator 550a, the second separator 550b, the interlayer 560, and the controller 570 are not described in greater detail herein.

As shown, a voltage monitor V₁ is positioned between the anode current collector 520 and the interlayer 560. A voltage monitor V₂ is positioned between the cathode current collector 540 and the interlayer 560. A pullup/pulldown DPI is connected to the interlayer 560 and a variable frequency voltage source VFS represented as a three-terminal device, connecting the anode current collector 520, the cathode current collector 540, and the interlayer 560. While the variable frequency voltage source VFS is shown as a three-terminal device, many different types of circuits can be used to create the voltage source. In some embodiments, a constant voltage, frequency dependent, or variable voltage source can be used to provide a relative potential to the interlayer 560. In some embodiments, the method 10 described above with reference to FIG. 2 can be applied to the electrochemical cell system 500.

The circuit shown in FIG. 6 can have the functionality to implement a frequency-based waveform into the electrochemical cell system 500. Implementation of a fixed or variable waveform to the electrochemical cell system 500 allows the use of advanced filtering to determine the electrical characteristics. The circuit evaluations can be in the form of a fast Fourier transform (FFT), finite impulse response (FIR), infinite impulse response (IIR), or any other form of advanced filtering to determine changes to the equivalent circuit parameters in a time, frequency, and/or other domain. AI can also be utilized to learn response behaviors and predict and/or diagnose behavior.

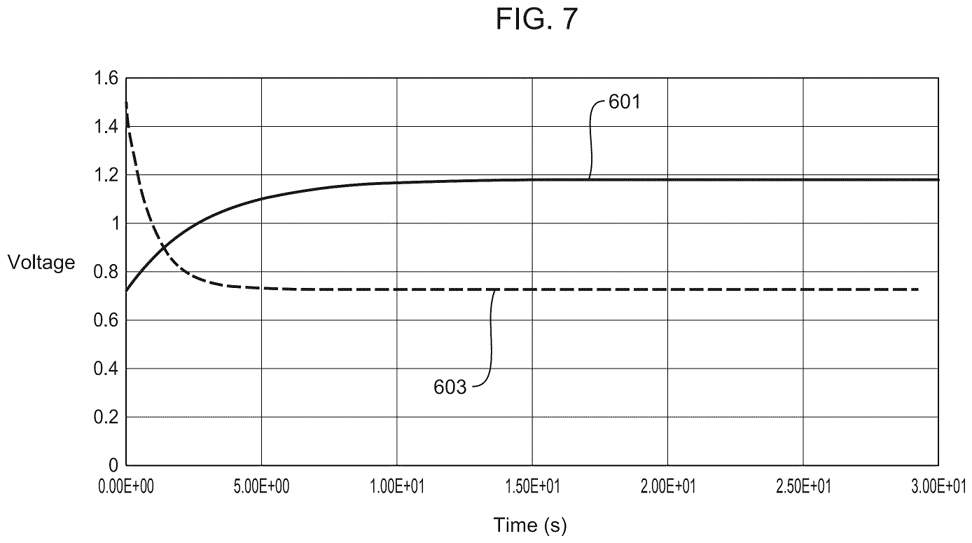

FIG. 7 is a graphical representation of a calibrating charge curve and a calibrating discharge curve, according to an embodiment. The curve is plotted as voltage vs. time. Curve 601 (e.g., solid line) represents a charge curve and Curve 603 (e.g., dashed line) represents a discharge curve. These curves represent calibration parameters of an interlayer (e.g., interlayer 160 or any other interlayer described herein) when its associated electrochemical cell system (e.g., electrochemical cell system 100 or any other electrochemical cell system described herein) is disturbed with a fixed resistance value (e.g., known resistance R₁). The target value of the voltage curve is determined by the electrochemical relationship of the interlayer to the other electrodes (e.g., anode 110, cathode 130), and can be determined by Equation 1 and Equation 2, as described above.

Equation 1 and Equation 2 create a predictable response curve for the evaluation of the health of the electrodes and the connections therebetween in real time. Additionally, standard curve fitting can be used to estimate both the circuit elements and the response of the interlayer to such stimuli. This can also be modified in real time with AI advanced filtering. In some embodiments, the curves 601, 603 may be representative of charge and/or discharge curves of any of the electrochemical cell systems (e.g., electrochemical cell systems 100, 200, 300, 400, 500) as described herein, which may include any of the electrochemical cells (e.g., electrochemical cells 102, 202, 302, 402, 502) as described herein, any of the components and/or features as described herein, and/or may be configured to perform any of the methods and/or operations as described herein. All such variations are described herein and should be considered as part of the present disclosure.

Various concepts may be embodied as one or more methods, of which at least one example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments. Put differently, it is to be understood that such features may not necessarily be limited to a particular order of execution, but rather, any number of threads, processes, services, servers, and/or the like that may execute serially, asynchronously, concurrently, in parallel, simultaneously, synchronously, and/or the like in a manner consistent with the disclosure. As such, some of these features may be mutually contradictory, in that they cannot be simultaneously present in a single embodiment. Similarly, some features are applicable to one aspect of the innovations, and inapplicable to others.

In addition, the disclosure may include other innovations not presently described. Applicant reserves all rights in such innovations, including the right to embodiment such innovations, file additional applications, continuations, continuations-in-part, divisionals, and/or the like thereof. As such, it should be understood that advantages, embodiments, examples, functional, features, logical, operational, organizational, structural, topological, and/or other aspects of the disclosure are not to be considered limitations on the disclosure as defined by the embodiments or limitations on equivalents to the embodiments. Depending on the particular desires and/or characteristics of an individual and/or enterprise user, database configuration and/or relational model, data type, data transmission and/or network framework, syntax structure, and/or the like, various embodiments of the technology disclosed herein may be implemented in a manner that enables a great deal of flexibility and customization as described herein.

All definitions, as defined and used herein, should be understood to control over dictionary definitions, definitions in documents incorporated by reference, and/or ordinary meanings of the defined terms.

As used herein, in particular embodiments, the terms “about” or “approximately” when preceding a numerical value indicates the value plus or minus a range of 10%. Where a range of values is provided, it is understood that each intervening value, to the tenth of the unit of the lower limit unless the context clearly dictates otherwise, between the upper and lower limit of that range and any other stated or intervening value in that stated range is encompassed within the disclosure. That the upper and lower limits of these smaller ranges can independently be included in the smaller ranges is also encompassed within the disclosure, subject to any specifically excluded limit in the stated range. Where the stated range includes one or both of the limits, ranges excluding either or both of those included limits are also included in the disclosure.

The phrase “and/or,” as used herein in the specification and in the embodiments, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the embodiments, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the embodiments, “consisting of,” will refer to the inclusion of exactly one element of a number or list of elements. In general, the term “or” as used herein shall only be interpreted as indicating exclusive alternatives (i.e., “one or the other but not both”) when preceded by terms of exclusivity, such as “either,” “one of,” “only one of,” or “exactly one of.” “Consisting essentially of,” when used in the embodiments, shall have its ordinary meaning as used in the field of patent law.

As used herein in the specification and in the embodiments, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

In the embodiments, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

While specific embodiments of the present disclosure have been outlined above, many alternatives, modifications, and variations will be apparent to those skilled in the art. Accordingly, the embodiments set forth herein are intended to be illustrative, not limiting. Various changes may be made without departing from the spirit and scope of the disclosure. Where methods and steps described above indicate certain events occurring in a certain order, those of ordinary skill in the art having the benefit of this disclosure would recognize that the ordering of certain steps may be modified and such modification are in accordance with the variations of the invention. Additionally, certain of the steps may be performed concurrently in a parallel process when possible, as well as performed sequentially as described above. The embodiments have been particularly shown and described, but it will be understood that various changes in form and details may be made.

1. A method of evaluating an electrochemical cell, the electrochemical cell including a first electrode disposed on a first current collector, a second electrode disposed on a second current collector, a first separator, a second separator, and an interlayer disposed between the first separator and the second separator, the method comprising:
performing a calibrating electrical energy transfer between the first electrode and the second electrode;
determining a plurality of calibration voltage differences between the first electrode and the interlayer;
determining a baseline parameter based on the calibration voltage differences;
performing an operational electrical energy transfer between the first electrode and the second electrode;
determining a plurality of operational voltage differences between the first electrode and the interlayer;
determining an operational parameter based on the operational voltage differences; and
diagnosing a performance issue with the electrochemical cell based on the baseline parameter and the operational parameter.

2. The method of claim 1, wherein the calibrating electrical energy transfer includes an initial charge of the electrochemical cell and the operational electrical energy transfer includes a subsequent charge of the electrochemical cell.

3. The method of claim 1, wherein the calibrating electrical energy transfer includes an initial discharge of the electrochemical cell and the operational electrical energy transfer includes a subsequent discharge of the electrochemical cell.

4. The method of claim 1, wherein the first electrode includes an anode.

5. The method of claim 1, wherein the performance issue includes a lack of electrical connectivity between a testing circuit and the interlayer.

6. The method of claim 1, wherein the first electrode includes a cathode.

7. The method of claim 1, wherein the calibrating electrical energy transfer is a first calibrating electrical energy transfer, the plurality of calibration voltage differences are a first plurality of calibration voltage differences, the baseline parameter is a first baseline parameter, the operational electrical energy transfer is a first operational electrical energy transfer, the plurality of operational voltage differences are a first plurality of operational voltage differences, and the operational parameter is a first operational parameter, the method further comprising:
performing a first stimulation of the interlayer via at least one of a pullup or a pulldown;
performing a second calibrating electrical energy transfer between the first electrode and the second electrode;
determining a second plurality of calibration voltage differences between the first electrode and the interlayer;
determining a second baseline parameter based on the second plurality of calibration voltage differences;
performing a second stimulation to the interlayer, the second stimulation including the at least one of the pullup or the pulldown of the first stimulation;
performing a second operational electrical energy transfer between the first electrode and the second electrode;
determining a plurality of second operational voltage differences between the first electrode and the interlayer;
determining a second operational parameter based on the plurality of second operational voltage differences; and
based on a difference between the second baseline parameter and the second operational parameter, diagnosing the performance issue with the electrochemical cell.

8. The method of claim 7, wherein the performance issue includes at least one of a connection issue in the electrochemical cell or a dendrite formed in the first electrode.

9. The method of claim 1, wherein the baseline parameter is described by equation:
$${v}_{𝔱} = Δ V ( 1 - {e}^{t / τ} )$$
where:
vₜ is a time-dependent voltage difference between the first electrode and the interlayer;
ΔV is an applied voltage difference between the first electrode and the interlayer;
t is time; and
τ is an RC time constant.

10. The method of claim 9, wherein diagnosing the performance issue with the electrochemical cell includes determining a difference between the RC time constant of the baseline parameter and an RC time constant of the operational parameter.

11. The method of claim 1, wherein the calibrating electrical energy transfer is a first calibrating electrical energy transfer, the plurality of calibration voltage differences are a first plurality of calibration voltage differences, the baseline parameter is a first baseline parameter, the operational electrical energy transfer is a first operational electrical energy transfer, the plurality of operational voltage differences are a first plurality of operational voltage differences, and the operational parameter is a first operational parameter, the method further comprising:
changing a resistance of a circuit connecting the first electrode to the interlayer;
performing a second calibrating electrical energy transfer between the first electrode and the second electrode;
determining a second plurality of calibration voltage differences between the first electrode and the interlayer;
determining a second baseline parameter based on the second plurality of calibration voltage differences;
performing a stimulation to the interlayer via at least one of a pullup or a pulldown;
performing a second operational electrical energy transfer between the first electrode and the second electrode;
determining a plurality of second operational voltage differences between the first electrode and the interlayer;
determining a second operational parameter based on the plurality of second operational voltage differences; and
based on a difference between the second baseline parameter and the second operational parameter, diagnosing the performance issue with the electrochemical cell.

12. The method of claim 11, wherein the first and second calibrating electrical energy transfers or the first and second operational electrical energy transfers are executed via a constant voltage source.

13. The method of claim 11, wherein the first and second calibrating electrical energy transfers or the first and second operational electrical energy transfers are executed via a variable frequency voltage source.

14. The method of claim 11, wherein at least one of the first calibrating electrical energy transfer or the first operational electrical energy transfer includes at least one of an electron transfer or an ion transfer.

15. The method of claim 1, wherein diagnosing the performance issue with the electrochemical cell includes evaluating an average deviation between the baseline parameter and the operational parameter.

16. A method of evaluating a plurality of electrochemical cells connected in parallel, each electrochemical cell of the plurality of electrochemical cells including a first electrode disposed on a first current collector, a second electrode disposed on a second current collector, a first separator, a second separator, and an interlayer disposed between the first separator and the second separator, the method comprising:
electrically coupling each interlayer of each electrochemical cell from the plurality of electrochemical cells at a common interlayer connection point;
electrically coupling the first electrode of each electrochemical cell from the plurality of electrochemical cells at a common electrode connection point; and
measuring a voltage between the common interlayer connection point and the common electrode connection point.

17. The method of claim 16, further comprising:
based on a voltage measurement within a range deemed to correspond to a healthy electrochemical cell, recycling the plurality of electrochemical cells.

18. The method of claim 16, further comprising:
based on a voltage measurement outside of a range deemed to correspond to a healthy electrochemical cell, measuring an individual electrode voltage difference between the interlayer and the first electrode of each electrochemical cell.

19. The method of claim 18, further comprising:
discarding each electrochemical cell from the plurality of electrochemical cells having an individual electrode voltage difference outside of the range deemed to correspond to a healthy electrochemical cell.

20. The method of claim 18, further comprising:
recycling at least a portion the plurality of electrochemical cells, the portion including an electrochemical cell having an individual electrode voltage difference within the range corresponding to a healthy electrochemical cell.

21. A system, comprising:
an electrochemical cell, including:
an anode;
a cathode;
a first separator disposed on the anode;
a second separator disposed on the cathode; and
an interlayer between the first separator and the second separator; and
a controller operably coupled to the electrochemical cell, the controller configured to:
cause a calibrating electrical energy transfer between the anode and the cathode;
determine a plurality of calibration voltage differences between at least one of the anode or the cathode, and the interlayer;
determine a baseline parameter based on the calibration voltage differences;
cause an operational electrical energy transfer between the anode and the cathode;
determine a plurality of operational voltage differences between at least one of the anode or the cathode, and the interlayer;
determine an operational parameter based on the operational voltage differences; and
diagnose a performance issue with the electrochemical cell based on the baseline parameter and the operational parameter.

22. The system of claim 21, wherein:
the calibrating electrical energy transfer includes an initial charge of the electrochemical cell, and
the operational electrical energy transfer includes a subsequent charge of the electrochemical cell.

23. The system of claim 21, wherein:
the calibrating electrical energy transfer includes an initial discharge of the electrochemical cell, and
the operational electrical energy transfer includes a subsequent discharge of the electrochemical cell.

24. The system of claim 21, wherein the performance issue includes a lack of electrical connectivity between a testing circuit and the interlayer.

25. The system of claim 21, wherein the calibrating electrical energy transfer is a first calibrating electrical energy transfer, the plurality of calibration voltage differences are a first plurality of calibration voltage differences, the baseline parameter is a first baseline parameter, the operational electrical energy transfer is a first operational electrical energy transfer, the plurality of operational voltage differences are a first plurality of operational voltage differences, and the operational parameter is a first operational parameter, the controller further configured to:
cause a first stimulation of the interlayer via at least one of a pullup or a pulldown;
cause a second calibrating electrical energy transfer between anode and the cathode;
determine a second plurality of calibration voltage differences between at least one of the anode or the cathode, and the interlayer;
determine a second baseline parameter based on the second plurality of calibration voltage differences;
cause a second stimulation to the interlayer, the second stimulation including the at least one of the pullup or the pulldown of the first stimulation;
cause a second operational electrical energy transfer between the anode and the cathode;
determine a plurality of second operational voltage differences between at least one of the anode or the cathode, and the interlayer;
determine a second operational parameter based on the plurality of second operational voltage differences; and
diagnose the performance issue with the electrochemical cell based also on a difference between the second baseline parameter and the second operational parameter.

26. The system of claim 25, wherein the performance issue includes at least one of a connection issue in the electrochemical cell or a dendrite growth in at least one of the anode or the cathode.

27. The system of claim 21, wherein the baseline parameter is described by equation:
$${v}_{t} = Δ V ( 1 - {e}^{t / τ} )$$
where:
vₜ is a time-dependent voltage difference between at least one of the cathode or the anode, and the interlayer;
ΔV is an applied voltage difference between the at least one of the cathode or the anode, and the interlayer;
t is time; and
τ is an RC time constant.

28. The system of claim 21, wherein the calibrating electrical energy transfer is a first calibrating electrical energy transfer, the plurality of calibration voltage differences are a first plurality of calibration voltage differences, the baseline parameter is a first baseline parameter, the operational electrical energy transfer is a first operational electrical energy transfer, the plurality of operational voltage differences are a first plurality of operational voltage differences, and the operational parameter is a first operational parameter, the controller further configured to:
cause a change in a resistance of a circuit connecting at least one of the anode or the cathode to the interlayer;
cause a second calibrating electrical energy transfer between the anode and the cathode;
determine a second plurality of calibration voltage differences between at least one of the anode or the cathode, and the interlayer;
determine a second baseline parameter based on the second plurality of calibration voltage differences;
cause a stimulation to the interlayer via at least one of a pullup or a pulldown;
cause a second operational electrical energy transfer between the anode and the cathode;
determine a plurality of second operational voltage differences between at least one of the anode or the cathode and the interlayer;
determine a second operational parameter based on the plurality of second operational voltage differences; and
diagnose the performance issue with the electrochemical cell based also on a difference between the second baseline parameter and the second operational parameter.

29. The system of claim 28, wherein at least one of the first and second calibrating electrical energy transfers or the first and second operational electrical energy transfers are executed via at least one of a constant voltage source or a variable frequency voltage source.

30. The system of claim 21, wherein the anode includes an anode active material on an anode current collector, and the cathode includes a cathode active material on a cathode current collector, the controller operably coupled to the interlayer, the anode current collector, and the cathode current collector.
